(19) United States
(12) Patent Application Publication
(10) Pub. No.: US 2025/0385756 A1
(43) Pub. Date: Dec. 18, 2025

(54) INTERLEAVER BASED TONE RESERVATION

(71) Applicant: QUALCOMM Incorporated, San Diego, CA (US)

(72) Inventors: David YUNUSOV, Holon (IL); Amit BAR-OR TILLINGER, Tel-Aviv (IL); Gideon Shlomo KUTZ, Ramat Hasharon (IL)

(21) Appl. No.: 18/746,915

(22) Filed: Jun. 18, 2024

(51) Int. Cl. H04L 1/00

(52) U.S. Cl. CPC H04L 1/0071; H04L 1/0061

(57) ABSTRACT

Various aspects of the present disclosure generally relate to wireless communication. In some aspects, a wireless communication device may interleave a plurality of coded bits to form a plurality of interleaved coded bits. The plurality of coded bits may include a set of systematic bits and a set of parity bits. The set of systematic bits may be mapped to a first set of resources, in a plurality of resources of a communication channel, and the set of parity bits may be mapped to a second set of resources, in the plurality of resources of the communication channel, and wherein peak reduction tones are overlapped with one or more resources of the second set of resources. The wireless communication device may transmit a communication including the plurality of interleaved coded bits and the peak reduction tones. Numerous other aspects are described.

### FIELD OF THE DISCLOSURE

Aspects of the present disclosure generally relate to wireless communication and specifically relate to techniques, apparatuses, and methods for interleaver based tone reservation.

### BACKGROUND

Wireless communication systems are widely deployed to provide various services that may include carrying voice, text, messaging, video, data, and/or other traffic. The services may include unicast, multicast, and/or broadcast services, among other examples. Typical wireless communication systems may employ multiple-access radio access technologies (RATs) capable of supporting communication with multiple users by sharing available system resources (for example, time domain resources, frequency domain resources, spatial domain resources, and/or device transmit power, among other examples). Examples of such multiple-access RATs include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

The above multiple-access RATs have been adopted in various telecommunication standards to provide common protocols that enable different wireless communication devices to communicate on a municipal, national, regional, or global level. An example telecommunication standard is New Radio (NR). NR, which may also be referred to as 5G, is part of a continuous mobile broadband evolution promulgated by the Third Generation Partnership Project (3GPP). NR (and other mobile broadband evolutions beyond NR) may be designed to better support Internet of things (IoT) and reduced capability device deployments, industrial connectivity, millimeter wave (mmWave) expansion, licensed and unlicensed spectrum access, non-terrestrial network (NTN) deployment, sidelink and other device-to-device direct communication technologies (for example, cellular vehicle-to-everything (CV2X) communication), massive multiple-input multiple-output (MIMO), disaggregated network architectures and network topology expansions, multiple-subscriber implementations, high-precision positioning, and/or radio frequency (RF) sensing, among other examples. As the demand for mobile broadband access continues to increase, further improvements in NR may be implemented, and other radio access technologies such as 6G may be introduced, to further advance mobile broadband evolution.

### SUMMARY

Some aspects described herein relate to a method of wireless communication performed by a wireless communication device. The method may include interleaving a plurality of coded bits to form a plurality of interleaved coded bits, the plurality of coded bits including a set of systematic bits and a set of parity bits, wherein the plurality of coded bits is interleaved such that the set of systematic bits is mapped to a first set of resources, in a plurality of resources of a communication channel, and the set of parity bits is mapped to a second set of resources, in the plurality of resources of the communication channel, and wherein peak reduction tones (PRTs) are overlapped with one or more resources of the second set of resources. The method may include transmitting a communication including the plurality of interleaved coded bits and the peak reduction tones.

Some aspects described herein relate to a method of wireless communication performed by a wireless communication device. The method may include receiving, via a set of subcarriers, a communication including a plurality of interleaved coded bits and PRTs, wherein the plurality of interleaved coded bits includes a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources. The method may include decoding the communication over all subcarriers included in the set of subcarriers.

Some aspects described herein relate to a non-transitory computer-readable medium that stores a set of instructions for wireless communication by a wireless communication device. The set of instructions, when executed by one or more processors of the wireless communication device, may cause the wireless communication device to interleave a plurality of coded bits to form a plurality of interleaved coded bits, the plurality of coded bits including a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein PRTs are overlapped with one or more resources of the second set of resources. The set of instructions, when executed by one or more processors of the wireless communication device, may cause the wireless communication device to transmit a communication including the plurality of interleaved coded bits and the PRTs.

Some aspects described herein relate to a non-transitory computer-readable medium that stores a set of instructions for wireless communication by a wireless communication device. The set of instructions, when executed by one or more processors of the wireless communication device, may cause the wireless communication device to receive, via a set of subcarriers, a communication including a plurality of interleaved coded bits and PRTs, wherein the plurality of interleaved coded bits includes a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources. The set of instructions, when executed by one or more processors of the wireless communication device, may cause the wireless communication device to decode the communication over all subcarriers included in the set of subcarriers.

Some aspects described herein relate to a wireless communication device for wireless communication. The wireless communication device may include one or more memories and one or more processors coupled to the one or more memories. The one or more processors may be configured to interleave a plurality of coded bits to form a plurality of interleaved coded bits, the plurality of coded bits including a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein PRTs are overlapped with one or more resources of the second set of resources. The one or more processors may be configured to transmit a communication including the plurality of interleaved coded bits and the PRTs.

Some aspects described herein relate to a wireless communication device for wireless communication. The wireless communication device may include one or more memories and one or more processors coupled to the one or more memories. The one or more processors may be configured to receive, via a set of subcarriers, a communication including a plurality of interleaved coded bits and PRTs, wherein the plurality of interleaved coded bits includes a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources. The one or more processors may be configured to decode the communication over all subcarriers included in the set of subcarriers.

Some aspects described herein relate to an apparatus for wireless communication. The apparatus may include means for interleaving a plurality of coded bits to form a plurality of interleaved coded bits, the plurality of coded bits including a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein PRTs are overlapped with one or more resources of the second set of resources. The apparatus may include means for transmitting a communication including the plurality of interleaved coded bits and the PRTs.

Some aspects described herein relate to an apparatus for wireless communication. The apparatus may include means for receiving, via a set of subcarriers, a communication including a plurality of interleaved coded bits and PRTs, wherein the plurality of interleaved coded bits includes a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources. The apparatus may include means for decoding the communication over all subcarriers included in the set of subcarriers.

Aspects of the present disclosure may generally be implemented by or as a method, apparatus, system, computer program product, non-transitory computer- readable medium, user equipment, base station, network node, network entity, wireless communication device, and/or processing system as substantially described with reference to, and as illustrated by, the specification and accompanying drawings.

The foregoing paragraphs of this section have broadly summarized some aspects of the present disclosure. These and additional aspects and associated advantages will be described hereinafter. The disclosed aspects may be used as a basis for modifying or designing other aspects for carrying out the same or similar purposes of the present disclosure. Such equivalent aspects do not depart from the scope of the appended claims. Characteristics of the aspects disclosed herein, both their organization and method of operation, together with associated advantages, will be better understood from the following description when considered in connection with the accompanying drawings.

### BRIEF DESCRIPTION OF THE DRAWINGS

The appended drawings illustrate some aspects of the present disclosure, but are not limiting of the scope of the present disclosure because the description may enable other aspects. Each of the drawings is provided for purposes of illustration and description, and not as a definition of the limits of the claims. The same or similar reference numbers in different drawings may identify the same or similar elements.

FIG. 1 is a diagram illustrating an example of a wireless communication network in accordance with the present disclosure.

FIG. 2 is a diagram illustrating an example network node in communication with an example user equipment (UE) in a wireless network in accordance with the present disclosure.

FIG. 3 is a diagram illustrating an example disaggregated base station architecture in accordance with the present disclosure.

FIGS. 4A-4C are diagrams illustrating examples associated with interleaving, in accordance with the present disclosure.

FIGS. 5A and 5B are diagrams illustrating an example of UE subcarrier tone reservation on one or more subcarriers, in accordance with the present disclosure.

FIG. 6 is a diagram illustrating an example associated with interleaver based tone reservation, in accordance with the present disclosure.

FIGS. 7A-7D are diagrams illustrating examples associated with channel aware interleaving, in accordance with the present disclosure.

FIG. 8 is a diagram illustrating an example process performed, for example, at a wireless communication device or an apparatus of a wireless communication device, in accordance with the present disclosure.

FIG. 9 is a diagram illustrating an example process performed, for example, at a wireless communication device or an apparatus of a wireless communication device, in accordance with the present disclosure.

FIG. 10 is a diagram of an example apparatus for wireless communication, in accordance with the present disclosure.

FIG. 11 is a diagram of an example apparatus for wireless communication, in accordance with the present disclosure.

### DETAILED DESCRIPTION

Various aspects of the present disclosure are described hereinafter with reference to the accompanying drawings. However, aspects of the present disclosure may be embodied in many different forms and is not to be construed as limited to any specific aspect illustrated by or described with reference to an accompanying drawing or otherwise presented in this disclosure. Rather, these aspects are provided so that this disclosure will be thorough and complete, and will fully convey the scope of the disclosure to those skilled in the art. One skilled in the art may appreciate that the scope of the disclosure is intended to cover any aspect of the disclosure disclosed herein, whether implemented independently of or in combination with any other aspect of the disclosure. For example, an apparatus may be implemented or a method may be practiced using various combinations or quantities of the aspects set forth herein. In addition, the scope of the disclosure is intended to cover an apparatus having, or a method that is practiced using, other structures and/or functionalities in addition to or other than the structures and/or functionalities with which various aspects of the disclosure set forth herein may be practiced. Any aspect of the disclosure disclosed herein may be embodied by one or more elements of a claim.

Several aspects of telecommunication systems will now be presented with reference to various methods, operations, apparatuses, and techniques. These methods, operations, apparatuses, and techniques will be described in the following detailed description and illustrated in the accompanying drawings by various blocks, modules, components, circuits, steps, processes, or algorithms (collectively referred to as “elements”). These elements may be implemented using hardware, software, or a combination of hardware and software. Whether such elements are implemented as hardware or software depends upon the particular application and design constraints imposed on the overall system.

A transmitter wireless communication device performs channel coding as part of a physical layer processing in association with transmitting a communication (e.g., a downlink communication, a sidelink communication, or the like). The transmitter wireless communication device may be configured to perform channel coding using a linear code that provides for error correction. One example of such a linear code is a low density parity check (LDPC) code. At the transmitter wireless communication device, an output from applying an LDPC code to a code block segment (and any associated cyclic redundancy check (CRC) bits) comprises a group of coded bits (i.e., a channel code segment) that includes a set of systematic bits and a set of parity bits. Generally speaking, the set of systematic bits includes the original data, and the set of parity bits is generated by channel coding that can be used for error correction (at a receiver wireless communication device). The output of channel coding—the group of coded bits—is then provided to a rate matching function.

The rate matching function processes each group of coded bits separately. Rate matching is performed in two stages: bit selection and bit interleaving. Bit selection is a process that reduces a quantity of channel coded bits to match a capacity of air-interface resources allocated for a transmission. During bit selection, the set of systematic bits is written into a circular buffer first, followed by the set of parity bits. For a given transmission, a set of bits is then extracted from the circular buffer using a specific starting position in the circular buffer, which is indicated via a redundancy version (RV) (e.g., RVO).

Bit interleaving reorders the group of bits after extraction from the circular buffer. Bit interleaving can help to avoid bursts of contiguous bit errors at an input of a channel decoder at the receiver wireless communication device. Performance of the decoder is improved when bit errors are distributed at random rather than in contiguous groups. Conventionally, bit interleaving involves the group of bits being written into a table row-by-row, and then being read out of the table column-by-column. The number of rows belonging to the table is set to be equal to a modulation order. This means that each column of the table corresponds to a single modulation symbol. In practice, the conventional operation of the interleaver causes systematic bits to be allocated to stronger constellation log likelihood ratio (LLR) values and causes parity bits to be allocated to comparatively weaker LLR values.

Notably, the conventional interleaver does not take channel conditions into account when performing interleaving. Rather, the conventional interleaver simply spreads all bits, which results in the systematic bits being allocated to stronger LLRs of a given constellation point and parity bits being allocated to weaker LLRs of the given constellation point. That is, the conventional interleaver performs bit interleaving without any channel awareness. However, conditions in a given resource (e.g., resource elements (REs), a resource block (RB), or the like) of the channel may be noisy, meaning that capacity on the given resource is reduced. This means that at least some systematic bits may be transmitted on resources that, due to channel conditions, have a lower capacity than other resources of the channel, which can unintentionally increase a code rate associated with the transmission (e.g., due to erasure on the low-capacity resources). As a result, a block error rate (BLER) associated with the transmission may be increased, meaning that reliability of successful reception and decoding of the transmission at the receiver wireless communication device is reduced.

A peak-to-average power ratio (PAPR) is a ratio of peak power (xₚₑₐₖ) to an average power of a signal. The average power of the signal may be determined based on a root mean square (RMS) value (x_{RMS}). Mathematically, PAPR may be represented by the following equation:

$$P A P R = \frac{{x}_{p e a k}^{2}}{{x}_{R M S}^{2}} .$$

In some cases, lowering a PAPR of a signal may increase an efficiency and/or a performance of a wireless communication device. For example, lowering the PAPR may increase the efficiency of a power amplifier of the transmitter or transmitting wireless communication device (e.g., the wireless communication device transmitting the signal), reduce in-band and/or out-of-band distortions, and/or increase a performance (e.g., by reducing in-band and/or out-of-band distortions) of the receiver or receiving wireless communication device (e.g., the wireless communication device receiving the signal).

In some cases, tone reservation may be used to improve a PAPR of a transmission. For example, a transmission may include one or more reserved subcarriers (e.g., tones) on which data and/or pilots (e.g., reference signals) are not transmitted. However, because data and/or pilots are not transmitted on the reserved subcarriers, the use of tone reservation may decrease overall throughput.

In a communication where tone reservation is not used, an increase in PAPR may occur. The increase in PAPR may degrade communications between the transmitter wireless communication device and the wireless communication device receiving the transmission and may negatively affect an efficiency of power amplification at the transmitter wireless communication device. Degradation of the communications may cause the transmitter wireless communication device and/or the receiver wireless communication device to consume power, communication, network, and computing resources to detect and/or correct communication errors associated with the degradation.

Various aspects relate generally to tone reservation based on channel aware interleaving. For example, in some aspects, a transmitter wireless communication device may interleave a plurality of coded bits comprising a set of systematic bits and a set of parity bits such that the set of parity bits is mapped to one or more resources for which a channel characteristic fails to satisfy a threshold. In some aspects, peak reduction tones (PRTs) are applied to the one or more resources to which the set of parity bits is mapped. Similarly, some aspects more specifically relate to performing de-interleaving of a plurality of interleaved coded bits based at least in part on channel characteristics of resources of a communication channel and PRTs being applied to one or more of the resources for which a channel characteristic fails to satisfy a threshold. For example, in some aspects, a receiver wireless communication device may de-interleave a plurality of interleaved coded bits to obtain a plurality of coded bits including a set of systematic bits and a set of parity bits, with the plurality of coded bits being de-interleaved based on the set of parity bits being mapped to the one or more resources to which PRTs are applied (e.g., the one or more resources for which a channel characteristic fails to satisfy the threshold.

Particular aspects of the subject matter described in this disclosure can be implemented to realize one or more of the following potential advantages. In some examples, the techniques and apparatuses for channel aware interleaving described herein can be used to increase a likelihood that systematic bits will be transmitted on resources of a communication channel that have sufficient capacity so as to reduce or eliminate an increase in code rate caused by noisy channel conditions. In this way, the techniques and apparatuses described herein can reduce BLER associated with a transmission (e.g., as compared to the use of conventional interleaving), meaning that reliability of successful reception and decoding of the transmission is increased. Further, throughput may be increased by applying PRTs to resources used to transmit a set of parity bits with little or no impact to a reception of the communication by the receiver wireless communication device.

Multiple-access radio access technologies (RATs) have been adopted in various telecommunication standards to provide common protocols that enable wireless communication devices to communicate on a municipal, enterprise, national, regional, or global level. For example, 5G New Radio (NR) is part of a continuous mobile broadband evolution promulgated by the Third Generation Partnership Project (3GPP). 5G NR supports various technologies and use cases including enhanced mobile broadband (eMBB), ultra-reliable low-latency communication (URLLC), massive machine-type communication (mMTC), millimeter wave (mmWave) technology, beamforming, network slicing, edge computing, Internet of Things (IOT) connectivity and management, and network function virtualization (NFV).

As the demand for broadband access increases and as technologies supported by wireless communication networks evolve, further technological improvements may be adopted in or implemented for 5G NR or future RATs, such as 6G, to further advance the evolution of wireless communication for a wide variety of existing and new use cases and applications. Such technological improvements may be associated with new frequency band expansion, licensed and unlicensed spectrum access, overlapping spectrum use, small cell deployments, non-terrestrial network (NTN) deployments, disaggregated network architectures and network topology expansion, device aggregation, advanced duplex communication, sidelink and other device-to-device direct communication, IoT (including passive or ambient IoT) networks, reduced capability (RedCap) UE functionality, industrial connectivity, multiple-subscriber implementations, high-precision positioning, radio frequency (RF) sensing, and/or artificial intelligence or machine learning (AI/ML), among other examples. These technological improvements may support use cases such as wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial and/or aerial platforms, among other examples. The methods, operations, apparatuses, and techniques described herein may enable one or more of the foregoing technologies and/or support one or more of the foregoing use cases.

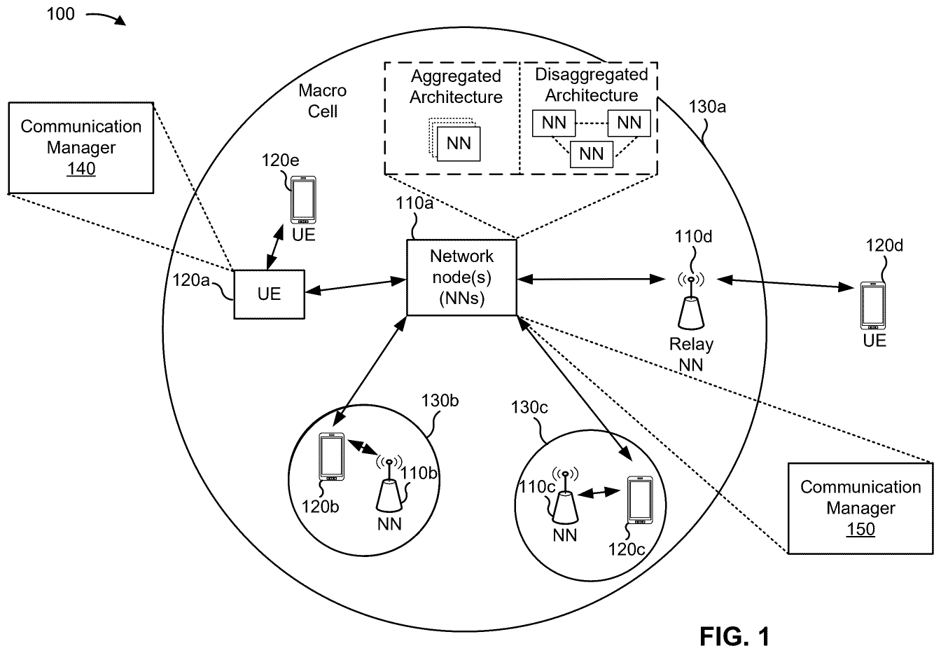

FIG. 1 is a diagram illustrating an example of a wireless communication network 100 in accordance with the present disclosure. The wireless communication network 100 may be or may include elements of a 5G (or NR) network or a 6G network, among other examples. The wireless communication network 100 may include multiple network nodes 110, shown as a network node (NN) 110a, a network node 110b, a network node 110c, and a network node 110d. The network nodes 110 may support communications with multiple UEs 120, shown as a UE 120a, a UE 120b, a UE 120c, a UE 120d, and a UE 120c.

The network nodes 110 and the UEs 120 of the wireless communication network 100 may communicate using the electromagnetic spectrum, which may be subdivided by frequency or wavelength into various classes, bands, carriers, and/or channels. For example, devices of the wireless communication network 100 may communicate using one or more operating bands. In some aspects, multiple wireless networks 100 may be deployed in a given geographic area. Each wireless communication network 100 may support a particular RAT (which may also be referred to as an air interface) and may operate on one or more carrier frequencies in one or more frequency ranges. Examples of RATs include a 4G RAT, a 5G/NR RAT, and/or a 6G RAT, among other examples. In some examples, when multiple RATs are deployed in a given geographic area, each RAT in the geographic area may operate on different frequencies to avoid interference with one another.

Various operating bands have been defined as frequency range designations FR1 (410 MHz through 7.125 GHZ), FR2 (24.25 GHz through 52.6 GHZ), FR3 (7.125GHz through 24.25 GHZ), FR4a or FR4-1 (52.6 GHz through 71 GHz), FR4 (52.6 GHZ through 114.25 GHZ), and FR5 (114.25 GHz through 300 GHz). Although a portion of FR1 is greater than 6 GHZ, FR1 is often referred to (interchangeably) as a “Sub −6 GHz” band in some documents and articles. Similarly, FR2 is often referred to (interchangeably) as a “millimeter wave” band in some documents and articles, despite being different than the extremely high frequency (EHF) band (30 GHz through 300 GHz), which is identified by the International Telecommunications Union (ITU) as a “millimeter wave” band. The frequencies between FR1 and FR2 are often referred to as mid-band frequencies, which include FR3. Frequency bands falling within FR3 may inherit FR1 characteristics or FR2 characteristics, and thus may effectively extend features of FR1 or FR2 into mid-band frequencies. Thus, “sub −6 GHz,” if used herein, may broadly refer to frequencies that are less than 6 GHZ, that are within FR1, and/or that are included in mid-band frequencies. Similarly, the term “millimeter wave,” if used herein, may broadly refer to frequencies that are included in mid-band frequencies, that are within FR2, FR4, FR4-a or FR4-1, or FR5, and/or that are within the EHF band. Higher frequency bands may extend 5G NR operation, 6G operation, and/or other RATs beyond 52.6 GHz. For example, each of FR4a, FR4-1, FR4, and FR5 falls within the EHF band. In some examples, the wireless communication network 100 may implement dynamic spectrum sharing (DSS), in which multiple RATs (for example, 4G/LTE and 5G/NR) are implemented with dynamic bandwidth allocation (for example, based on user demand) in a single frequency band. It is contemplated that the frequencies included in these operating bands (for example, FR1, FR2, FR3, FR4, FR4-a, FR4-1, and/or FR5) may be modified, and techniques described herein may be applicable to those modified frequency ranges.

A network node 110 may include one or more devices, components, or systems that enable communication between a UE 120 and one or more devices, components, or systems of the wireless communication network 100. A network node 110 may be, may include, or may also be referred to as an NR network node, a 5G network node, a 6G network node, a Node B, an eNB, a gNB, an access point (AP), a transmission reception point (TRP), a mobility element, a core, a network entity, a network element, a network equipment, and/or another type of device, component, or system included in a radio access network (RAN).

A network node 110 may be implemented as a single physical node (for example, a single physical structure) or may be implemented as two or more physical nodes (for example, two or more distinct physical structures). For example, a network node 110 may be a device or system that implements part of a radio protocol stack, a device or system that implements a full radio protocol stack (such as a full gNB protocol stack), or a collection of devices or systems that collectively implement the full radio protocol stack. For example, and as shown, a network node 110 may be an aggregated network node (having an aggregated architecture), meaning that the network node 110 may implement a full radio protocol stack that is physically and logically integrated within a single node (for example, a single physical structure) in the wireless communication network 100. For example, an aggregated network node 110 may consist of a single standalone base station or a single TRP that uses a full radio protocol stack to enable or facilitate communication between a UE 120 and a core network of the wireless communication network 100.

Alternatively, and as also shown, a network node 110 may be a disaggregated network node (sometimes referred to as a disaggregated base station), meaning that the network node 110 may implement a radio protocol stack that is physically distributed and/or logically distributed among two or more nodes in the same geographic location or in different geographic locations. For example, a disaggregated network node may have a disaggregated architecture. In some deployments, disaggregated network nodes 110 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating base station functionality into multiple units that can be individually deployed.

The network nodes 110 of the wireless communication network 100 may include one or more central units (CUs), one or more distributed units (DUs), and/or one or more radio units (RUs). A CU may host one or more higher layer control functions, such as radio resource control (RRC) functions, packet data convergence protocol (PDCP) functions, and/or service data adaptation protocol (SDAP) functions, among other examples. A DU may host one or more of a radio link control (RLC) layer, a medium access control (MAC) layer, and/or one or more higher physical (PHY) layers depending, at least in part, on a functional split, such as a functional split defined by the 3GPP. In some examples, a DU also may host one or more lower PHY layer functions, such as a fast Fourier transform (FFT), an inverse FFT (iFFT), beamforming, physical random access channel (PRACH) extraction and filtering, and/or scheduling of resources for one or more UEs 120, among other examples. An RU may host RF processing functions or lower PHY layer functions, such as an FFT, an iFFT, beamforming, or PRACH extraction and filtering, among other examples, according to a functional split, such as a lower layer functional split. In such an architecture, each RU can be operated to handle over the air (OTA) communication with one or more UEs 120.

In some aspects, a single network node 110 may include a combination of one or more CUs, one or more DUs, and/or one or more RUs. Additionally or alternatively, a network node 110 may include one or more Near-Real Time (Near-RT) RAN Intelligent Controllers (RICs) and/or one or more Non-Real Time (Non-RT) RICs. In some examples, a CU, a DU, and/or an RU may be implemented as a virtual unit, such as a virtual central unit (VCU), a virtual distributed unit (VDU), or a virtual radio unit (VRU), among other examples. A virtual unit may be implemented as a virtual network function, such as associated with a cloud deployment.

Some network nodes 110 (for example, a base station, an RU, or a TRP) may provide communication coverage for a particular geographic area. In the 3GPP, the term “cell” can refer to a coverage area of a network node 110 or to a network node 110 itself, depending on the context in which the term is used. A network node 110 may support one or multiple (for example, three) cells. In some examples, a network node 110 may provide communication coverage for a macro cell, a pico cell, a femto cell, or another type of cell. A macro cell may cover a relatively large geographic area (for example, several kilometers in radius) and may allow unrestricted access by UEs 120 with service subscriptions. A pico cell may cover a relatively small geographic area and may allow unrestricted access by UEs 120 with service subscriptions. A femto cell may cover a relatively small geographic area (for example, a home) and may allow restricted access by UEs 120 having association with the femto cell (for example, UEs 120 in a closed subscriber group (CSG)). A network node 110 for a macro cell may be referred to as a macro network node. A network node 110 for a pico cell may be referred to as a pico network node. A network node 110 for a femto cell may be referred to as a femto network node or an in-home network node. In some examples, a cell may not necessarily be stationary. For example, the geographic area of the cell may move according to the location of an associated mobile network node 110 (for example, a train, a satellite base station, an unmanned aerial vehicle, or an NTN network node).

The wireless communication network 100 may be a heterogeneous network that includes network nodes 110 of different types, such as macro network nodes, pico network nodes, femto network nodes, relay network nodes, aggregated network nodes, and/or disaggregated network nodes, among other examples. In the example shown in FIG. 1, the network node 110a may be a macro network node for a macro cell 130a, the network node 110b may be a pico network node for a pico cell 130b, and the network node 110c may be a femto network node for a femto cell 130c. Various different types of network nodes 110 may generally transmit at different power levels, serve different coverage areas, and/or have different impacts on interference in the wireless communication network 100 than other types of network nodes 110. For example, macro network nodes may have a high transmit power level (for example, 5 to 40 watts), whereas pico network nodes, femto network nodes, and relay network nodes may have lower transmit power levels (for example, 0.1 to 2 watts).

In some examples, a network node 110 may be, may include, or may operate as an RU, a TRP, or a base station that communicates with one or more UEs 120 via a radio access link (which may be referred to as a “Uu” link). The radio access link may include a downlink and an uplink. “Downlink” (or “DL”) refers to a communication direction from a network node 110 to a UE 120, and “uplink” (or “UL”) refers to a communication direction from a UE 120 to a network node 110. Downlink channels may include one or more control channels and one or more data channels. A downlink control channel may be used to transmit downlink control information (DCI) (for example, scheduling information, reference signals, and/or configuration information) from a network node 110 to a UE 120. A downlink data channel may be used to transmit downlink data (for example, user data associated with a UE 120) from a network node 110 to a UE 120. Downlink control channels may include one or more physical downlink control channels (PDCCHs), and downlink data channels may include one or more physical downlink shared channels (PDSCHs). Uplink channels may similarly include one or more control channels and one or more data channels. An uplink control channel may be used to transmit uplink control information (UCI) (for example, reference signals and/or feedback corresponding to one or more downlink transmissions) from a UE 120 to a network node 110. An uplink data channel may be used to transmit uplink data (for example, user data associated with a UE 120) from a UE 120 to a network node 110. Uplink control channels may include one or more physical uplink control channels (PUCCHs), and uplink data channels may include one or more physical uplink shared channels (PUSCHs). The downlink and the uplink may each include a set of resources on which the network node 110 and the UE 120 may communicate.

Downlink and uplink resources may include time domain resources (frames, subframes, slots, and/or symbols), frequency domain resources (frequency bands, component carriers, subcarriers, resource blocks, and/or resource elements), and/or spatial domain resources (particular transmit directions and/or beam parameters). Frequency domain resources of some bands may be subdivided into bandwidth parts (BWPs). A BWP may be a continuous block of frequency domain resources (for example, a continuous block of resource blocks) that are allocated for one or more UEs 120. A UE 120 may be configured with both an uplink BWP and a downlink BWP (where the uplink BWP and the downlink BWP may be the same BWP or different BWPs). A BWP may be dynamically configured (for example, by a network node 110 transmitting a DCI configuration to the one or more UEs 120) and/or reconfigured, which means that a BWP can be adjusted in real-time (or near-real-time) based on changing network conditions in the wireless communication network 100 and/or based on the specific requirements of the one or more UEs 120. This enables more efficient use of the available frequency domain resources in the wireless communication network 100 because fewer frequency domain resources may be allocated to a BWP for a UE 120 (which may reduce the quantity of frequency domain resources that a UE 120 is required to monitor), leaving more frequency domain resources to be spread across multiple UEs 120. Thus, BWPs may also assist in the implementation of lower-capability UEs 120 by facilitating the configuration of smaller bandwidths for communication by such UEs 120.

As described above, in some aspects, the wireless communication network 100 may be, may include, or may be included in, an IAB network. In an IAB network, at least one network node 110 is an anchor network node that communicates with a core network. An anchor network node 110 may also be referred to as an IAB donor (or “IAB-donor”). The anchor network node 110 may connect to the core network via a wired backhaul link. For example, an Ng interface of the anchor network node 110 may terminate at the core network. Additionally or alternatively, an anchor network node 110 may connect to one or more devices of the core network that provide a core access and mobility management function (AMF). An IAB network also generally includes multiple non-anchor network nodes 110, which may also be referred to as relay network nodes or simply as IAB nodes (or “IAB-nodes”). Each non-anchor network node 110 may communicate directly with the anchor network node 110 via a wireless backhaul link to access the core network, or may communicate indirectly with the anchor network node 110 via one or more other non-anchor network nodes 110 and associated wireless backhaul links that form a backhaul path to the core network. Some anchor network node 110 or other non-anchor network node 110 may also communicate directly with one or more UEs 120 via wireless access links that carry access traffic. In some examples, network resources for wireless communication (such as time resources, frequency resources, and/or spatial resources) may be shared between access links and backhaul links.

In some examples, any network node 110 that relays communications may be referred to as a relay network node, a relay station, or simply as a relay. A relay may receive a transmission of a communication from an upstream station (for example, another network node 110 or a UE 120) and transmit the communication to a downstream station (for example, a UE 120 or another network node 110). In this case, the wireless communication network 100 may include or be referred to as a “multi-hop network.” In the example shown in FIG. 1, the network node 110d (for example, a relay network node) may communicate with the network node 110a (for example, a macro network node) and the UE 120d in order to facilitate communication between the network node 110a and the UE 120d. Additionally or alternatively, a UE 120 may be or may operate as a relay station that can relay transmissions to or from other UEs 120. A UE 120 that relays communications may be referred to as a UE relay or a relay UE, among other examples.

The UEs 120 may be physically dispersed throughout the wireless communication network 100, and each UE 120 may be stationary or mobile. A UE 120 may be, may include, or may be included in an access terminal, another terminal, a mobile station, or a subscriber unit. A UE 120 may be, include, or be coupled with a cellular phone (for example, a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device, a biometric device, a wearable device (for example, a smart watch, smart clothing, smart glasses, a smart wristband, and/or smart jewelry, such as a smart ring or a smart bracelet), an entertainment device (for example, a music device, a video device, and/or a satellite radio), an XR device, a vehicular component or sensor, a smart meter or sensor, industrial manufacturing equipment, a Global Navigation Satellite System (GNSS) device (such as a Global Positioning System device or another type of positioning device), a UE function of a network node, and/or any other suitable device or function that may communicate via a wireless medium.

A UE 120 and/or a network node 110 may include one or more chips, system-on-chips (SoCs), chipsets, packages, or devices that individually or collectively constitute or comprise a processing system. The processing system includes processor (or “processing”) circuitry in the form of one or multiple processors, microprocessors, processing units (such as central processing units (CPUs), graphics processing units (GPUs), neural processing units (NPUs) and/or digital signal processors (DSPs)), processing blocks, application-specific integrated circuits (ASIC), programmable logic devices (PLDs) (such as field programmable gate arrays (FPGAs)), or other discrete gate or transistor logic or circuitry (all of which may be generally referred to herein individually as “processors” or collectively as “the processor” or “the processor circuitry”). One or more of the processors may be individually or collectively configurable or configured to perform various functions or operations described herein. A group of processors collectively configurable or configured to perform a set of functions may include a first processor configurable or configured to perform a first function of the set and a second processor configurable or configured to perform a second function of the set, or may include the group of processors all being configured or configurable to perform the set of functions.

The processing system may further include memory circuitry in the form of one or more memory devices, memory blocks, memory elements or other discrete gate or transistor logic or circuitry, each of which may include tangible storage media such as random-access memory (RAM) or read-only memory (ROM), or combinations thereof (all of which may be generally referred to herein individually as “memories” or collectively as “the memory” or “the memory circuitry”). One or more of the memories may be coupled (for example, operatively coupled, communicatively coupled, electronically coupled, or electrically coupled) with one or more of the processors and may individually or collectively store processor-executable code (such as software) that, when executed by one or more of the processors, may configure one or more of the processors to perform various functions or operations described herein. Additionally or alternatively, in some examples, one or more of the processors may be preconfigured to perform various functions or operations described herein without requiring configuration by software. The processing system may further include or be coupled with one or more modems (such as a Wi-Fi (for example, IEEE compliant) modem or a cellular (for example, 3GPP 4G LTE, 5G, or 6G compliant) modem). In some implementations, one or more processors of the processing system include or implement one or more of the modems. The processing system may further include or be coupled with multiple radios (collectively “the radio”), multiple RF chains, or multiple transceivers, each of which may in turn be coupled with one or more of multiple antennas. In some implementations, one or more processors of the processing system include or implement one or more of the radios, RF chains or transceivers. The UE 120 may include or may be included in a housing that houses components associated with the UE 120 including the processing system.

Some UEs 120 may be considered machine-type communication (MTC) UEs, evolved or enhanced machine-type communication (eMTC), UEs, further enhanced eMTC (feMTC) UEs, or enhanced feMTC (efeMTC) UEs, or further evolutions thereof, all of which may be simply referred to as “MTC UEs”). An MTC UE may be, may include, or may be included in or coupled with a robot, an uncrewed aerial vehicle, a remote device, a sensor, a meter, a monitor, and/or a location tag. Some UEs 120 may be considered IoT devices and/or may be implemented as NB-IoT (narrowband IoT) devices. An IoT UE or NB-IoT device may be, may include, or may be included in or coupled with an industrial machine, an appliance, a refrigerator, a doorbell camera device, a home automation device, and/or a light fixture, among other examples. Some UEs 120 may be considered Customer Premises Equipment, which may include telecommunications devices that are installed at a customer location (such as a home or office) to enable access to a service provider's network (such as included in or in communication with the wireless communication network 100).

Some UEs 120 may be classified according to different categories in association with different complexities and/or different capabilities. UEs 120 in a first category may facilitate massive IoT in the wireless communication network 100, and may offer low complexity and/or cost relative to UEs 120 in a second category. UEs 120 in a second category may include mission-critical IoT devices, legacy UEs, baseline UEs, high-tier UEs, advanced UEs, full-capability UEs, and/or premium UEs that are capable of URLLC, enhanced mobile broadband (eMBB), and/or precise positioning in the wireless communication network 100, among other examples. A third category of UEs 120 may have mid-tier complexity and/or capability (for example, a capability between UEs 120 of the first category and UEs 120 of the second capability). A UE 120 of the third category may be referred to as a reduced capacity UE (“RedCap UE”), a mid-tier UE, an NR-Light UE, and/or an NR-Lite UE, among other examples. RedCap UEs may bridge a gap between the capability and complexity of NB-IOT devices and/or eMTC UEs, and mission-critical IoT devices and/or premium UEs. RedCap UEs may include, for example, wearable devices, IoT devices, industrial sensors, and/or cameras that are associated with a limited bandwidth, power capacity, and/or transmission range, among other examples. RedCap UEs may support healthcare environments, building automation, electrical distribution, process automation, transport and logistics, and/or smart city deployments, among other examples.

In some examples, two or more UEs 120 (for example, shown as UE 120a and UE 120c) may communicate directly with one another using sidelink communications (for example, without communicating by way of a network node 110 as an intermediary). As an example, the UE 120a may directly transmit data, control information, or other signaling as a sidelink communication to the UE 120c. This is in contrast to, for example, the UE 120a first transmitting data in an UL communication to a network node 110, which then transmits the data to the UE 120c in a DL communication. In various examples, the UEs 120 may transmit and receive sidelink communications using peer-to-peer (P2P) communication protocols, device-to-device (D2D) communication protocols, vehicle-to-everything (V2X) communication protocols (which may include vehicle-to-vehicle (V2V) protocols, vehicle-to-infrastructure (V21) protocols, and/or vehicle-to-pedestrian (V2P) protocols), and/or mesh network communication protocols. In some deployments and configurations, a network node 110 may schedule and/or allocate resources for sidelink communications between UEs 120 in the wireless communication network 100. In some other deployments and configurations, a UE 120 (instead of a network node 110) may perform, or collaborate or negotiate with one or more other UEs to perform, scheduling operations, resource selection operations, and/or other operations for sidelink communications.

In various examples, some of the network nodes 110 and the UEs 120 of the wireless communication network 100 may be configured for full-duplex operation in addition to half-duplex operation. A network node 110 or a UE 120 operating in a half-duplex mode may perform only one of transmission or reception during particular time resources, such as during particular slots, symbols, or other time periods. Half-duplex operation may involve time-division duplexing (TDD), in which DL transmissions of the network node 110 and UL transmissions of the UE 120 do not occur in the same time resources (that is, the transmissions do not overlap in time). In contrast, a network node 110 or a UE 120 operating in a full-duplex mode can transmit and receive communications concurrently (for example, in the same time resources). By operating in a full-duplex mode, network nodes 110 and/or UEs 120 may generally increase the capacity of the network and the radio access link. In some examples, full-duplex operation may involve frequency-division duplexing (FDD), in which DL transmissions of the network node 110 are performed in a first frequency band or on a first component carrier and transmissions of the UE 120 are performed in a second frequency band or on a second component carrier different than the first frequency band or the first component carrier, respectively. In some examples, full-duplex operation may be enabled for a UE 120 but not for a network node 110. For example, a UE 120 may simultaneously transmit an UL transmission to a first network node 110 and receive a DL transmission from a second network node 110 in the same time resources. In some other examples, full-duplex operation may be enabled for a network node 110 but not for a UE 120. For example, a network node 110 may simultaneously transmit a DL transmission to a first UE 120 and receive an UL transmission from a second UE 120 in the same time resources. In some other examples, full-duplex operation may be enabled for both a network node 110 and a UE 120.

In some examples, the UEs 120 and the network nodes 110 may perform MIMO communication. “MIMO” generally refers to transmitting or receiving multiple signals (such as multiple layers or multiple data streams) simultaneously over the same time and frequency resources. MIMO techniques generally exploit multipath propagation. MIMO may be implemented using various spatial processing or spatial multiplexing operations. In some examples, MIMO may support simultaneous transmission to multiple receivers, referred to as multi-user MIMO (MU-MIMO). Some RATs may employ advanced MIMO techniques, such as mTRP operation (including redundant transmission or reception on multiple TRPs), reciprocity in the time domain or the frequency domain, single-frequency-network (SFN) transmission, or non-coherent joint transmission (NC-JT).

In some aspects, a wireless communication device (e.g., a network node 110 or a UE 120) may include a communication manager 140. As described in more detail elsewhere herein, the communication manager 140 may interleave a plurality of coded bits to form a plurality of interleaved coded bits, the plurality of coded bits including a set of systematic bits and a set of parity bits, wherein the plurality of coded bits is interleaved such that the set of systematic bits is mapped to a first set of resources, in a plurality of resources of a communication channel, and the set of parity bits is mapped to a second set of resources, in the plurality of resources of the communication channel, and wherein peak reduction tones (PRTs) are overlapped with one or more resources of the second set of resources; and transmit a communication including the plurality of interleaved coded bits and the PRTs. Additionally, or alternatively, the communication manager 140 may perform one or more other operations described herein.

In some aspects, the wireless communication device may include a communication manager 150. As described in more detail elsewhere herein, the communication manager 150 may receive, via a set of subcarriers, a communication including a plurality of interleaved coded bits and PRTs, wherein the plurality of interleaved coded bits includes a set of systematic bits and a set of parity bits, wherein the plurality of interleaved coded bits is interleaved such that the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources; and decode the communication over all subcarriers included in the set of subcarriers. Additionally, or alternatively, the communication manager 150 may perform one or more other operations described herein.

As indicated above, FIG. 1 is provided as an example. Other examples may differ from what is described with regard to FIG. 1.

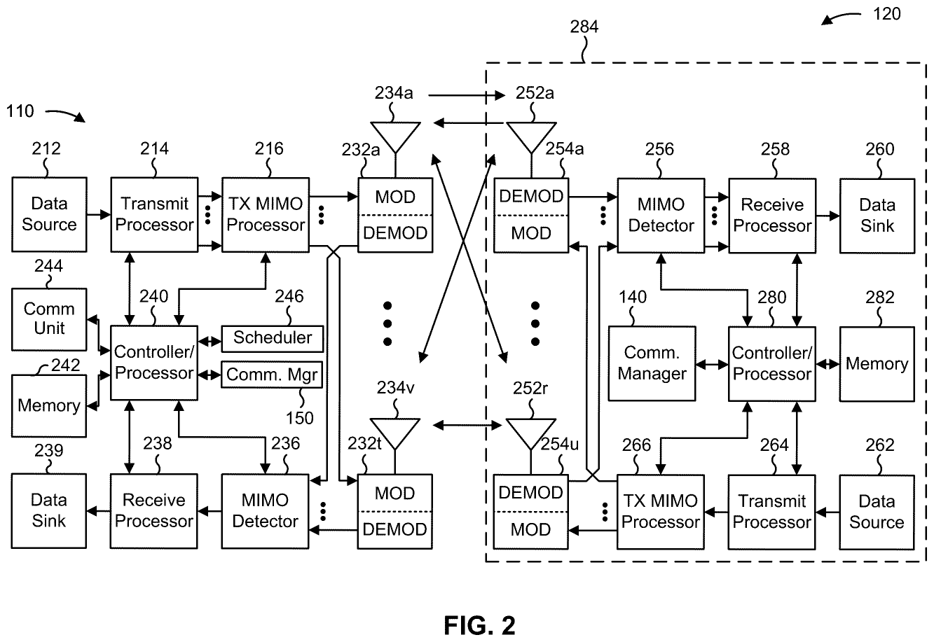

FIG. 2 is a diagram illustrating an example network node 110 in communication with an example UE 120 in a wireless network in accordance with the present disclosure.

As shown in FIG. 2, the network node 110 may include a data source 212, a transmit processor 214, a transmit (TX) MIMO processor 216, a set of modems 232 (shown as 232a through 232t, where t≥1), a set of antennas 234 (shown as 234a through 234v, where v≥1), a MIMO detector 236, a receive processor 238, a data sink 239, a controller/processor 240, a memory 242, a communication unit 244, a scheduler 246, and/or a communication manager 150, among other examples. In some configurations, one or a combination of the antenna(s) 234, the modem(s) 232, the MIMO detector 236, the receive processor 238, the transmit processor 214, and/or the TX MIMO processor 216 may be included in a transceiver of the network node 110. The transceiver may be under control of and used by one or more processors, such as the controller/processor 240, and in some aspects in conjunction with processor-readable code stored in the memory 242, to perform aspects of the methods, processes, and/or operations described herein. In some aspects, the network node 110 may include one or more interfaces, communication components, and/or other components that facilitate communication with the UE 120 or another network node.

The terms “processor,” “controller,” or “controller/processor” may refer to one or more controllers and/or one or more processors. For example, reference to “a/the processor,” “a/the controller/processor,” or the like (in the singular) should be understood to refer to any one or more of the processors described in connection with FIG. 2, such as a single processor or a combination of multiple different processors. Reference to “one or more processors” should be understood to refer to any one or more of the processors described in connection with FIG. 2. For example, one or more processors of the network node 110 may include transmit processor 214, TX MIMO processor 216, MIMO detector 236, receive processor 238, and/or controller/processor 240. Similarly, one or more processors of the UE 120 may include MIMO detector 256, receive processor 258, transmit processor 264, TX MIMO processor 266, and/or controller/processor 280.

In some aspects, a single processor may perform all of the operations described as being performed by the one or more processors. In some aspects, a first set of (one or more) processors of the one or more processors may perform a first operation described as being performed by the one or more processors, and a second set of (one or more) processors of the one or more processors may perform a second operation described as being performed by the one or more processors. The first set of processors and the second set of processors may be the same set of processors or may be different sets of processors. Reference to “one or more memories” should be understood to refer to any one or more memories of a corresponding device, such as the memory described in connection with FIG. 2. For example, operation described as being performed by one or more memories can be performed by the same subset of the one or more memories or different subsets of the one or more memories.

For downlink communication from the network node 110 to the UE 120, the transmit processor 214 may receive data (“downlink data”) intended for the UE 120 (or a set of UEs that includes the UE 120) from the data source 212 (such as a data pipeline or a data queue). In some examples, the transmit processor 214 may select one or more MCSs for the UE 120 in accordance with one or more channel quality indicators (CQIs) received from the UE 120. The network node 110 may process the data (for example, including encoding the data) for transmission to the UE 120 on a downlink in accordance with the MCS(s) selected for the UE 120 to generate data symbols. The transmit processor 214 may process system information (for example, semi-static resource partitioning information (SRPI)) and/or control information (for example, CQI requests, grants, and/or upper layer signaling) and provide overhead symbols and/or control symbols. The transmit processor 214 may generate reference symbols for reference signals (for example, a cell-specific reference signal (CRS), a demodulation reference signal (DMRS), or a channel state information (CSI) reference signal (CSI-RS)) and/or synchronization signals (for example, a primary synchronization signal (PSS) or a secondary synchronization signals (SSS)).

The TX MIMO processor 216 may perform spatial processing (for example, precoding) on the data symbols, the control symbols, the overhead symbols, and/or the reference symbols, if applicable, and may provide a set of output symbol streams (for example, T output symbol streams) to the set of modems 232. For example, each output symbol stream may be provided to a respective modulator component (shown as MOD) of a modem 232. Each modem 232 may use the respective modulator component to process (for example, to modulate) a respective output symbol stream (for example, for orthogonal frequency division multiplexing (OFDM)) to obtain an output sample stream. Each modem 232 may further use the respective modulator component to process (for example, convert to analog, amplify, filter, and/or upconvert) the output sample stream to obtain a time domain downlink signal. The modems 232a through 232t may together transmit a set of downlink signals (for example, T downlink signals) via the corresponding set of antennas 234.

A downlink signal may include a DCI communication, a MAC control element (MAC-CE) communication, an RRC communication, a downlink reference signal, or another type of downlink communication. Downlink signals may be transmitted on a PDCCH, a PDSCH, and/or on another downlink channel. A downlink signal may carry one or more transport blocks (TBs) of data. A TB may be a unit of data that is transmitted over an air interface in the wireless communication network 100. A data stream (for example, from the data source 212) may be encoded into multiple TBs for transmission over the air interface. The quantity of TBs used to carry the data associated with a particular data stream may be associated with a TB size common to the multiple TBs. The TB size may be based on or otherwise associated with radio channel conditions of the air interface, the MCS used for encoding the data, the downlink resources allocated for transmitting the data, and/or another parameter. In general, the larger the TB size, the greater the amount of data that can be transmitted in a single transmission, which reduces signaling overhead. However, larger TB sizes may be more prone to transmission and/or reception errors than smaller TB sizes, but such errors may be mitigated by more robust error correction techniques.

For uplink communication from the UE 120 to the network node 110, uplink signals from the UE 120 may be received by an antenna 234, may be processed by a modem 232 (for example, a demodulator component, shown as DEMOD, of a modem 232), may be detected by the MIMO detector 236 (for example, a receive (Rx) MIMO processor) if applicable, and/or may be further processed by the receive processor 238 to obtain decoded data and/or control information. The receive processor 238 may provide the decoded data to a data sink 239 (which may be a data pipeline, a data queue, and/or another type of data sink) and provide the decoded control information to a processor, such as the controller/processor 240.

The network node 110 may use the scheduler 246 to schedule one or more UEs 120 for downlink or uplink communications. In some aspects, the scheduler 246 may use DCI to dynamically schedule DL transmissions to the UE 120 and/or UL transmissions from the UE 120. In some examples, the scheduler 246 may allocate recurring time domain resources and/or frequency domain resources that the UE 120 may use to transmit and/or receive communications using an RRC configuration (for example, a semi-static configuration), for example, to perform semi-persistent scheduling (SPS) or to configure a configured grant (CG) for the UE 120.

One or more of the transmit processor 214, the TX MIMO processor 216, the modem 232, the antenna 234, the MIMO detector 236, the receive processor 238, and/or the controller/processor 240 may be included in an RF chain of the network node 110. An RF chain may include one or more filters, mixers, oscillators, amplifiers, analog-to-digital converters (ADCs), and/or other devices that convert between an analog signal (such as for transmission or reception via an air interface) and a digital signal (such as for processing by one or more processors of the network node 110). In some aspects, the RF chain may be or may be included in a transceiver of the network node 110.

In some examples, the network node 110 may use the communication unit 244 to communicate with a core network and/or with other network nodes. The communication unit 244 may support wired and/or wireless communication protocols and/or connections, such as Ethernet, optical fiber, common public radio interface (CPRI), and/or a wired or wireless backhaul, among other examples. The network node 110 may use the communication unit 244 to transmit and/or receive data associated with the UE 120 or to perform network control signaling, among other examples. The communication unit 244 may include a transceiver and/or an interface, such as a network interface.

The UE 120 may include a set of antennas 252 (shown as antennas 252a through 252r, where r≥1), a set of modems 254 (shown as modems 254a through 254u, where u≥1), a MIMO detector 256, a receive processor 258, a data sink 260, a data source 262, a transmit processor 264, a TX MIMO processor 266, a controller/processor 280, a memory 282, and/or a communication manager 140, among other examples. One or more of the components of the UE 120 may be included in a housing 284. In some aspects, one or a combination of the antenna(s) 252, the modem(s) 254, the MIMO detector 256, the receive processor 258, the transmit processor 264, or the TX MIMO processor 266 may be included in a transceiver that is included in the UE 120. The transceiver may be under control of and used by one or more processors, such as the controller/processor 280, and in some aspects in conjunction with processor-readable code stored in the memory 282, to perform aspects of the methods, processes, or operations described herein. In some aspects, the UE 120 may include another interface, another communication component, and/or another component that facilitates communication with the network node 110 and/or another UE 120.

For downlink communication from the network node 110 to the UE 120, the set of antennas 252 may receive the downlink communications or signals from the network node 110 and may provide a set of received downlink signals (for example, R received signals) to the set of modems 254. For example, each received signal may be provided to a respective demodulator component (shown as DEMOD) of a modem 254. Each modem 254 may use the respective demodulator component to condition (for example, filter, amplify, downconvert, and/or digitize) a received signal to obtain input samples. Each modem 254 may use the respective demodulator component to further demodulate or process the input samples (for example, for OFDM) to obtain received symbols. The MIMO detector 256 may obtain received symbols from the set of modems 254, may perform MIMO detection on the received symbols if applicable, and may provide detected symbols. The receive processor 258 may process (for example, decode) the detected symbols, may provide decoded data for the UE 120 to the data sink 260 (which may include a data pipeline, a data queue, and/or an application executed on the UE 120), and may provide decoded control information and system information to the controller/processor 280.

For uplink communication from the UE 120 to the network node 110, the transmit processor 264 may receive and process data (“uplink data”) from a data source 262 (such as a data pipeline, a data queue, and/or an application executed on the UE 120) and control information from the controller/processor 280. The control information may include one or more parameters, feedback, one or more signal measurements, and/or other types of control information. In some aspects, the receive processor 258 and/or the controller/processor 280 may determine, for a received signal (such as received from the network node 110 or another UE), one or more parameters relating to transmission of the uplink communication. The one or more parameters may include a reference signal received power (RSRP) parameter, a received signal strength indicator (RSSI) parameter, a reference signal received quality (RSRQ) parameter, a CQI parameter, or a transmit power control (TPC) parameter, among other examples. The control information may include an indication of the RSRP parameter, the RSSI parameter, the RSRQ parameter, the CQI parameter, the TPC parameter, and/or another parameter. The control information may facilitate parameter selection and/or scheduling for the UE 120 by the network node 110.

The transmit processor 264 may generate reference symbols for one or more reference signals, such as an uplink DMRS, an uplink sounding reference signal (SRS), and/or another type of reference signal. The symbols from the transmit processor 264 may be precoded by the TX MIMO processor 266, if applicable, and further processed by the set of modems 254 (for example, for DFT-s-OFDM or CP-OFDM). The TX MIMO processor 266 may perform spatial processing (for example, precoding) on the data symbols, the control symbols, the overhead symbols, and/or the reference symbols, if applicable, and may provide a set of output symbol streams (for example, U output symbol streams) to the set of modems 254. For example, each output symbol stream may be provided to a respective modulator component (shown as MOD) of a modem 254. Each modem 254 may use the respective modulator component to process (for example, to modulate) a respective output symbol stream (for example, for OFDM) to obtain an output sample stream. Each modem 254 may further use the respective modulator component to process (for example, convert to analog, amplify, filter, and/or upconvert) the output sample stream to obtain an uplink signal.

The modems 254a through 254u may transmit a set of uplink signals (for example, R uplink signals or U uplink symbols) via the corresponding set of antennas 252. An uplink signal may include a UCI communication, a MAC-CE communication, an RRC communication, or another type of uplink communication. Uplink signals may be transmitted on a PUSCH, a PUCCH, and/or another type of uplink channel. An uplink signal may carry one or more TBs of data. Sidelink data and control transmissions (that is, transmissions directly between two or more UEs 120) may generally use similar techniques as were described for uplink data and control transmission, and may use sidelink-specific channels such as a physical sidelink shared channel (PSSCH), a physical sidelink control channel (PSCCH), and/or a physical sidelink feedback channel (PSFCH).

One or more antennas of the set of antennas 252 or the set of antennas 234 may include, or may be included within, one or more antenna panels, one or more antenna groups, one or more sets of antenna elements, or one or more antenna arrays, among other examples. An antenna panel, an antenna group, a set of antenna elements, or an antenna array may include one or more antenna elements (within a single housing or multiple housings), a set of coplanar antenna elements, a set of non-coplanar antenna elements, or one or more antenna elements coupled with one or more transmission or reception components, such as one or more components of FIG. 2. As used herein, “antenna” can refer to one or more antennas, one or more antenna panels, one or more antenna groups, one or more sets of antenna elements, or one or more antenna arrays. “Antenna panel” can refer to a group of antennas (such as antenna elements) arranged in an array or panel, which may facilitate beamforming by manipulating parameters of the group of antennas. “Antenna module” may refer to circuitry including one or more antennas, which may also include one or more other components (such as filters, amplifiers, or processors) associated with integrating the antenna module into a wireless communication device.

In some examples, each of the antenna elements of an antenna 234 or an antenna 252 may include one or more sub-elements for radiating or receiving radio frequency signals. For example, a single antenna element may include a first sub-element cross-polarized with a second sub-clement that can be used to independently transmit cross-polarized signals. The antenna elements may include patch antennas, dipole antennas, and/or other types of antennas arranged in a linear pattern, a two-dimensional pattern, or another pattern. A spacing between antenna elements may be such that signals with a desired wavelength transmitted separately by the antenna elements may interact or interfere constructively and destructively along various directions (such as to form a desired beam). For example, given an expected range of wavelengths or frequencies, the spacing may provide a quarter wavelength, a half wavelength, or another fraction of a wavelength of spacing between neighboring antenna elements to allow for the desired constructive and destructive interference patterns of signals transmitted by the separate antenna elements within that expected range.

The amplitudes and/or phases of signals transmitted via antenna elements and/or sub-elements may be modulated and shifted relative to each other (such as by manipulating phase shift, phase offset, and/or amplitude) to generate one or more beams, which is referred to as beamforming. The term “beam” may refer to a directional transmission of a wireless signal toward a receiving device or otherwise in a desired direction. “Beam” may also generally refer to a direction associated with such a directional signal transmission, a set of directional resources associated with the signal transmission (for example, an angle of arrival, a horizontal direction, and/or a vertical direction), and/or a set of parameters that indicate one or more aspects of a directional signal, a direction associated with the signal, and/or a set of directional resources associated with the signal. In some implementations, antenna elements may be individually selected or deselected for directional transmission of a signal (or signals) by controlling amplitudes of one or more corresponding amplifiers and/or phases of the signal(s) to form one or more beams. The shape of a beam (such as the amplitude, width, and/or presence of side lobes) and/or the direction of a beam (such as an angle of the beam relative to a surface of an antenna array) can be dynamically controlled by modifying the phase shifts, phase offsets, and/or amplitudes of the multiple signals relative to each other.

Different UEs 120 or network nodes 110 may include different numbers of antenna elements. For example, a UE 120 may include a single antenna element, two antenna elements, four antenna elements, eight antenna elements, or a different number of antenna elements. As another example, a network node 110 may include eight antenna elements, 24 antenna elements, 64 antenna elements, 128 antenna elements, or a different number of antenna elements. Generally, a larger number of antenna elements may provide increased control over parameters for beam generation relative to a smaller number of antenna elements, whereas a smaller number of antenna elements may be less complex to implement and may use less power than a larger number of antenna elements. Multiple antenna elements may support multiple-layer transmission, in which a first layer of a communication (which may include a first data stream) and a second layer of a communication (which may include a second data stream) are transmitted using the same time and frequency resources with spatial multiplexing.

While blocks in FIG. 2 are illustrated as distinct components, the functions described above with respect to the blocks may be implemented in a single hardware, software, or combination component or in various combinations of components. For example, the functions described with respect to the transmit processor 264, the receive processor 258, and/or the TX MIMO processor 266 may be performed by or under the control of the controller/processor 280.

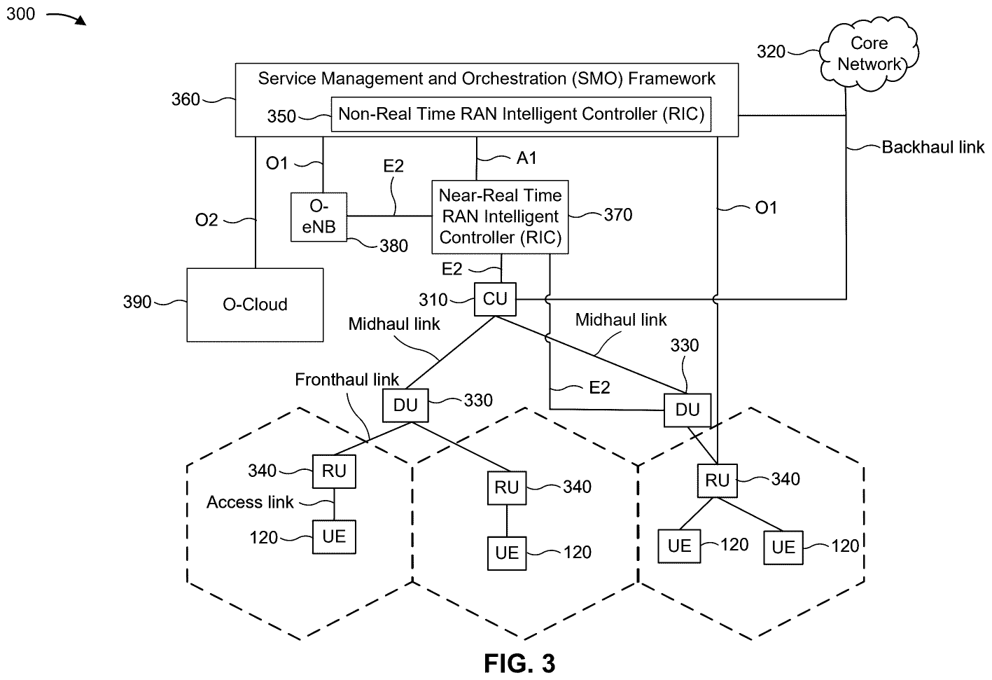

FIG. 3 is a diagram illustrating an example disaggregated base station architecture 300 in accordance with the present disclosure. One or more components of the example disaggregated base station architecture 300 may be, may include, or may be included in one or more network nodes (such one or more network nodes 110). The disaggregated base station architecture 300 may include a CU 310 that can communicate directly with a core network 320 via a backhaul link, or that can communicate indirectly with the core network 320 via one or more disaggregated control units, such as a Non-RT RIC 350 associated with a Service Management and Orchestration (SMO) Framework 360 and/or a Near-RT RIC 370 (for example, via an E2 link). The CU 310 may communicate with one or more DUs 330 via respective midhaul links, such as via F1 interfaces. Each of the DUs 330 may communicate with one or more RUs 340 via respective fronthaul links. Each of the RUs 340 may communicate with one or more UEs 120 via respective RF access links. In some deployments, a UE 120 may be simultaneously served by multiple RUs 340.

Each of the components of the disaggregated base station architecture 300, including the CUs 310, the DUs 330, the RUs 340, the Near-RT RICs 370, the Non-RT RICs 350, and the SMO Framework 360, may include one or more interfaces or may be coupled with one or more interfaces for receiving or transmitting signals, such as data or information, via a wired or wireless transmission medium.

In some aspects, the CU 310 may be logically split into one or more CU user plane (CU-UP) units and one or more CU control plane (CU-CP) units. A CU-UP unit may communicate bidirectionally with a CU-CP unit via an interface, such as the El interface when implemented in an O-RAN configuration. The CU 310 may be deployed to communicate with one or more DUs 330, as necessary, for network control and signaling. Each DU 330 may correspond to a logical unit that includes one or more base station functions to control the operation of one or more RUs 340. For example, a DU 330 may host various layers, such as an RLC layer, a MAC layer, or one or more PHY layers, such as one or more high PHY layers or one or more low PHY layers. Each layer (which also may be referred to as a module) may be implemented with an interface for communicating signals with other layers (and modules) hosted by the DU 330, or for communicating signals with the control functions hosted by the CU 310. Each RU 340 may implement lower layer functionality. In some aspects, real-time and non-real-time aspects of control and user plane communication with the RU(s) 340 may be controlled by the corresponding DU 330.

The SMO Framework 360 may support RAN deployment and provisioning of non-virtualized and virtualized network elements. For non-virtualized network elements, the SMO Framework 360 may support the deployment of dedicated physical resources for RAN coverage requirements, which may be managed via an operations and maintenance interface, such as an O1 interface. For virtualized network elements, the SMO Framework 360 may interact with a cloud computing platform (such as an open cloud (O-Cloud) platform 390) to perform network element life cycle management (such as to instantiate virtualized network elements) via a cloud computing platform interface, such as an O2 interface. A virtualized network element may include, but is not limited to, a CU 310, a DU 330, an RU 340, a non-RT RIC 350, and/or a Near-RT RIC 370. In some aspects, the SMO Framework 360 may communicate with a hardware aspect of a 4G RAN, a 5G NR RAN, and/or a 6G RAN, such as an open eNB (O-eNB) 380, via an O1 interface. Additionally or alternatively, the SMO Framework 360 may communicate directly with each of one or more RUs 340 via a respective O1 interface. In some deployments, this configuration can enable each DU 330 and the CU 310 to be implemented in a cloud-based RAN architecture, such as a vRAN architecture.

The Non-RT RIC 350 may include or may implement a logical function that enables non-real-time control and optimization of RAN elements and resources, AI/ML workflows including model training and updates, and/or policy-based guidance of applications and/or features in the Near-RT RIC 370. The Non-RT RIC 350 may be coupled to or may communicate with (such as via an A1 interface) the Near-RT RIC 370. The Near-RT RIC 370 may include or may implement a logical function that enables near-real-time control and optimization of RAN elements and resources via data collection and actions via an interface (such as via an E2 interface) connecting one or more CUs 310, one or more DUs 330, and/or an O-eNB with the Near-RT RIC 370.

In some aspects, to generate AI/ML models to be deployed in the Near-RT RIC 370, the Non-RT RIC 350 may receive parameters or external enrichment information from external servers. Such information may be utilized by the Near-RT RIC 370 and may be received at the SMO Framework 360 or the Non-RT RIC 350 from non-network data sources or from network functions. In some examples, the Non-RT RIC 350 or the Near-RT RIC 370 may tune RAN behavior or performance. For example, the Non-RT RIC 350 may monitor long-term trends and patterns for performance and may employ AI/ML models to perform corrective actions via the SMO Framework 360 (such as reconfiguration via an Ol interface) or via creation of RAN management policies (such as Al interface policies).

As indicated above, FIG. 3 is provided as an example. Other examples may differ from what is described with regard to FIG. 3.

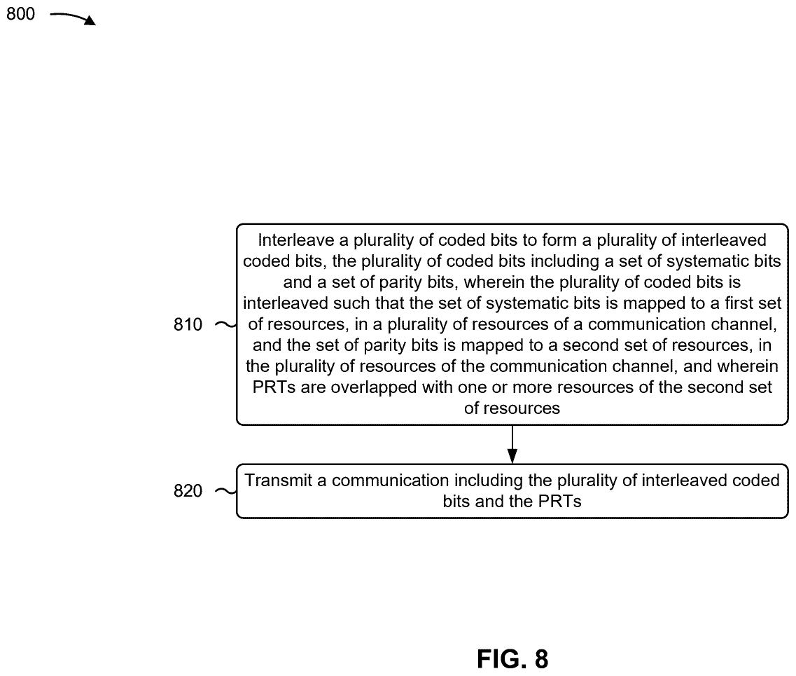

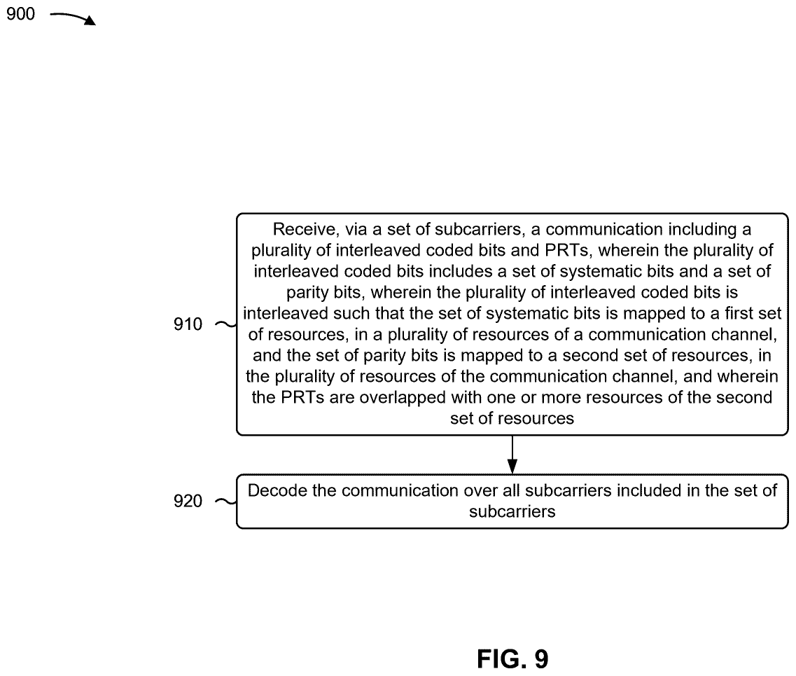

The network node 110, the controller/processor 240 of the network node 110, the UE 120, the controller/processor 280 of the UE 120, the CU 310, the DU 330, the RU 340, or any other component(s) of FIG. 1, 2, or 3 may implement one or more techniques or perform one or more operations associated with interleaver based tone reservation, as described in more detail elsewhere herein. For example, the controller/processor 240 of the network node 110, the controller/processor 280 of the UE 120, any other component(s) of FIG. 2, the CU 310, the DU 330, or the RU 340 may perform or direct operations of, for example, process 800 of FIG. 8, process 900 of FIG. 9, or other processes as described herein (alone or in conjunction with one or more other processors). The memory 242 may store data and program codes for the network node 110, the network node 110, the CU 310, the DU 330, or the RU 340. The memory 282 may store data and program codes for the UE 120. In some examples, the memory 242 or the memory 282 may include a non-transitory computer-readable medium storing a set of instructions (for example, code or program code) for wireless communication. The memory 242 may include one or more memories, such as a single memory or multiple different memories (of the same type or of different types). The memory 282 may include one or more memories, such as a single memory or multiple different memories (of the same type or of different types). For example, the set of instructions, when executed (for example, directly, or after compiling, converting, or interpreting) by one or more processors of the network node 110, the UE 120, the CU 310, the DU 330, or the RU 340, may cause the one or more processors to perform process 800 of FIG. 8, process 900 of FIG. 9, or other processes as described herein. In some examples, executing instructions may include running the instructions, converting the instructions, compiling the instructions, and/or interpreting the instructions, among other examples.

In some aspects, a wireless communication device (e.g., a network node 110, a UE 120) includes means for interleaving a plurality of coded bits to form a plurality of interleaved coded bits, the plurality of coded bits including a set of systematic bits and a set of parity bits, wherein the plurality of coded bits is interleaved such that the set of systematic bits is mapped to a first set of resources, in a plurality of resources of a communication channel, and the set of parity bits is mapped to a second set of resources, in the plurality of resources of the communication channel, and wherein PRTs are overlapped with one or more resources of the second set of resources; and/or means for transmitting a communication including the plurality of interleaved coded bits and the PRTs. In some aspects, the means for the wireless communication device to perform operations described herein may include, for example, one or more of communication manager 140, antenna 252, modem 254, MIMO detector 256, receive processor 258, transmit processor 264, TX MIMO processor 266, controller/processor 280, or memory 282. In some aspects, the means for the wireless communication device to perform operations described herein may include, for example, one or more of communication manager 150, transmit processor 214, TX MIMO processor 216, modem 232, antenna 234, MIMO detector 236, receive processor 238, controller/processor 240, memory 242, or scheduler 246.

In some aspects, a wireless communication device (e.g., a network node 110, a UE 120) includes means for receiving, via a set of subcarriers, a communication including a plurality of interleaved coded bits and PRTs, wherein the plurality of interleaved coded bits includes a set of systematic bits and a set of parity bits, wherein the plurality of interleaved coded bits is interleaved such that the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources; and/or means for decoding the communication over all subcarriers included in the set of subcarriers. In some aspects, the means for the wireless communication device to perform operations described herein may include, for example, one or more of communication manager 150, transmit processor 214, TX MIMO processor 216, modem 232, antenna 234, MIMO detector 236, receive processor 238, controller/processor 240, memory 242, or scheduler 246. In some aspects, the means for the wireless communication device to perform operations described herein may include, for example, one or more of communication manager 140, antenna 252, modem 254, MIMO detector 256, receive processor 258, transmit processor 264, TX MIMO processor 266, controller/processor 280, or memory 282.

As indicated above, FIG. 3 is provided as an example. Other examples may differ from what is described with regard to FIG. 3.

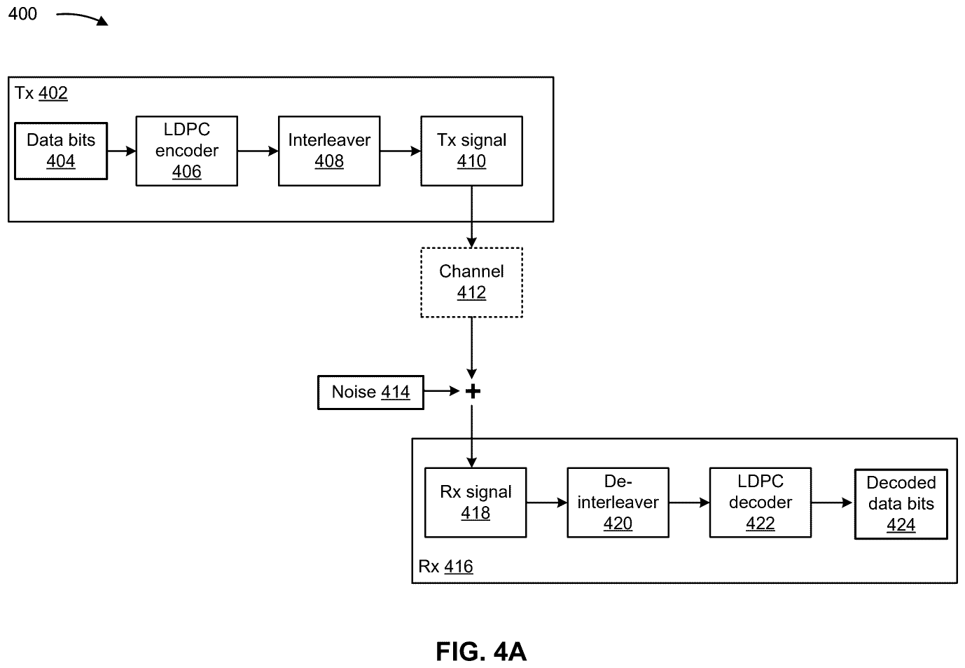

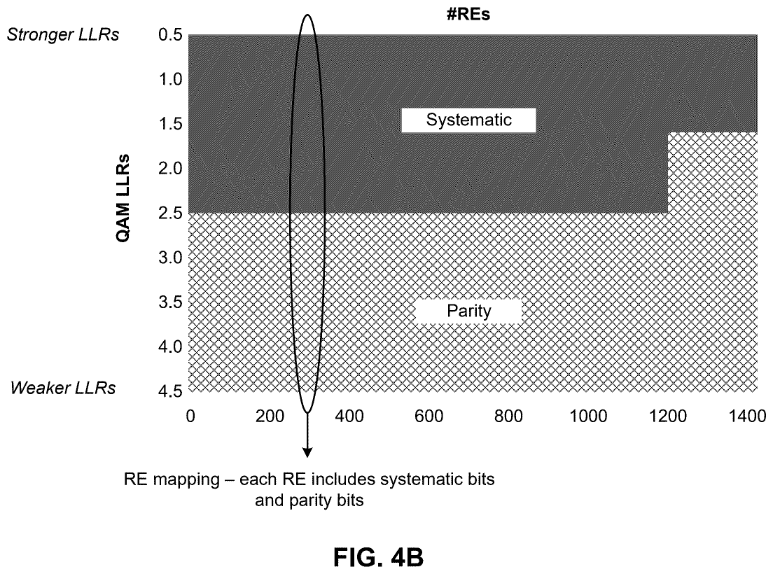

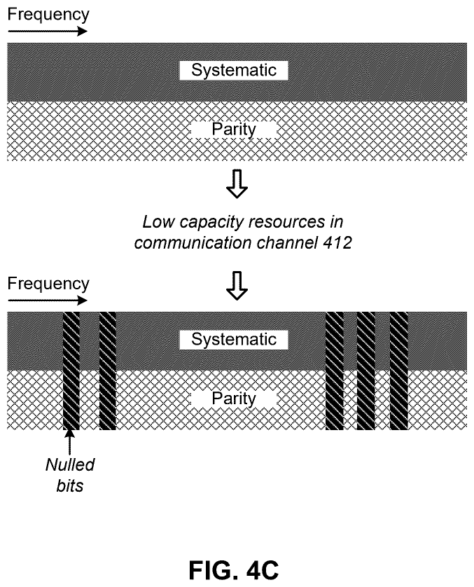

FIGS. 4A-4C are diagrams illustrating examples associated with interleaving, in accordance with the present disclosure.

FIG. 4A is a diagram illustrating an example 400 associated with transmission and reception of a communication using interleaving as described herein. As shown in FIG. 4A, at a transmitter wireless communication device (Tx) 402, data bits 404 are provided to an LDPC encoder 406, and an output of the LDPC encoder 406 (i.e., a plurality of coded bits) is provided to an interleaver 408. Here, the interleaver 408 maps systematic bits to stronger constellation LLR values and parity bits to weaker LLR values without taking into account conditions of a communication channel, as described above. An output of the interleaver 408 is provided for further processing and a Tx signal 410 is generated. The Tx signal 410 is transmitted in a communication channel 412 (e.g., a communication channel comprising a plurality of REs). As shown, noise 414 is introduced during transmission in the communication channel 412.

A receiver wireless communication device (Rx) 416 receives an Rx signal 418. The Rx signal 418 is processed at the Rx 416, and a plurality of interleaved coded bits is provided to a (conventional) de-interleaver 420. Here, the de-interleaver 420 de-interleaves the plurality of interleaved coded bits. Generally speaking, the de-interleaver 420 reverses the interleaving performed by the interleaver 408, and so conditions of the communication channel are not taken into account with respect to de-interleaving of the plurality of interleaved encoded bits. An output of the de-interleaver 420 (e.g., a plurality of de-interleaved coded bits) is provided to an LDPC decoder 422, and the LDPC decoder 422 decodes the plurality of de-interleaved coded bits to obtain a plurality of decoded data bits 424.

FIG. 4B illustrates an example of a result of interleaving as performed by the interleaver 408 without taking into account conditions of the communication channel 412. As indicated in FIG. 4B, each column of the diagram represents an RE (e.g., a subcarrier), and each row of the diagram represents an LLR of the constellation. 16 quadrature amplitude modulation (QAM) is used in this example, and so there are four bits, with each row corresponding to one of the four bits. As indicated in FIG. 4B, the interleaving performed by the interleaver 408 results in a mapping of the plurality of coded bits to the REs such that each RE (i.e., each column) includes both systematic bits and parity bits (e.g., two systematic bits and two parity bits).

FIG. 4C illustrates an example of an impact of lower capacity resources on a transmission that uses interleaving as described with respect to FIGS. 4A and 4B. As indicated in the upper diagram of FIG. 4C (and as described above), the interleaver 408 maps the plurality of coded bits such that each RE (i.e., each column) includes both systematic bits and parity bits. As indicated, the communication channel 412 may comprise some relatively low capacity resources, and transmission of bits in these resources may be unreliable due to lack of sufficient energy that causes the bits to be nulled (e.g., such that the bits are not successfully received at the receiver wireless communication device). As shown in the lower diagram of FIG. 4C, in the case of conventional interleaving, the nulled bits may include a significant number of systematic bits, which is undesirable because the loss of systematic bits increases a code rate and, further, increases a likelihood that coded bits received at the Rx 416 are not successfully decoded. Notably, the loss of the parity bits is less impactful because the parity bits are used for error correction of the systematic bits (rather than carrying actual data).

As indicated above, FIGS. 4A-4C are provided as an example. Other examples may differ from what is described with respect to FIGS. 4A-4C.

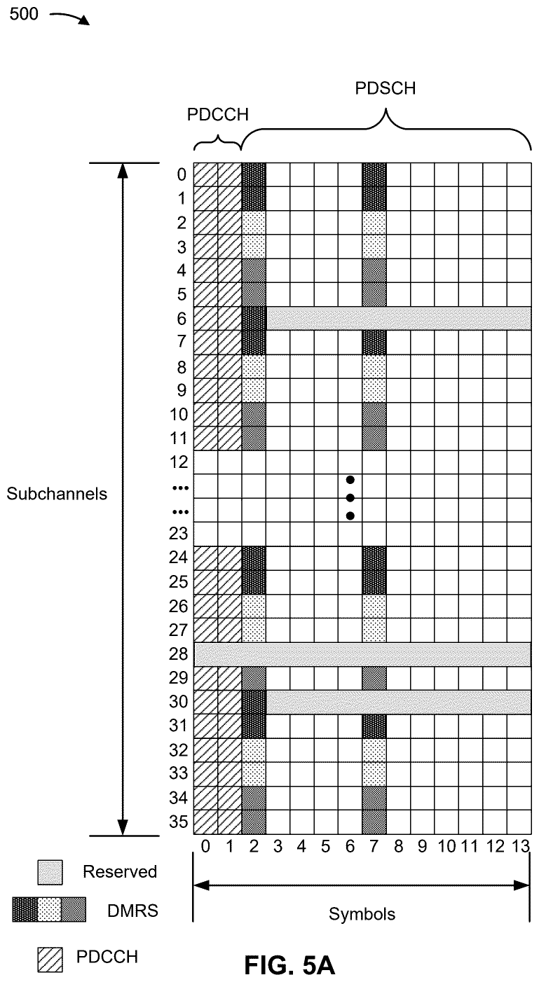

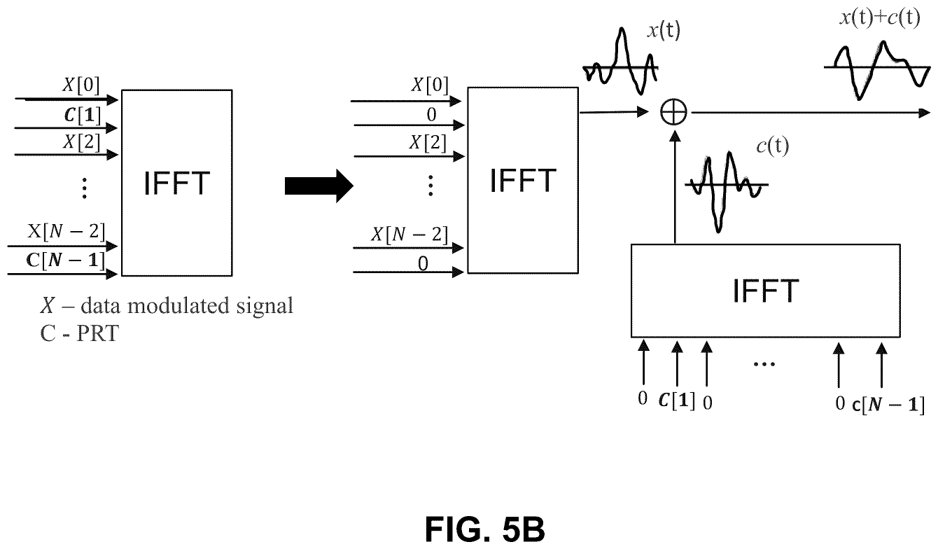

FIGS. 5A and 5B are diagrams illustrating an example 500 of UE subcarrier tone reservation on one or more subcarriers, in accordance with the present disclosure. In some networks, a network node may transmit a downlink transmission on a physical downlink shared channel (PDSCH) with tone reservation on one or more subcarriers based at least in part on measurement(s) of uplink signals from a UE, a request from the UE, an indication of a capability of the UE, and/or an independent determination by the network node, among other examples (e.g., as described herein).

In some aspects, the UE may be configured to communicate with the network node with a configuration for tone reservation. For example, the configuration may be common for multiple communications (e.g., for a configured grant and/or semi-persistent scheduling resources), multiple UEs connected to the network node, a beam provided by the network node, a cell provided by the network node, and/or the like.

Tone reservation may reduce PAPR by reserving PRTs within a set of resources allocated for transmitting a signal. As shown by example 500, a PDSCH may include one or more reserved subcarriers (e.g., tones) on which data and/or pilots are not to be transmitted. In some aspects, the subcarriers may be empty (e.g., not having any information intended for transmission to the UE). Additionally, or alternatively, the subcarriers may comprise an anti-peak signal (also referred to as a correctional signal or a peaks cancelling signal). The anti-peak signal may comprise a signal that, when added to a data modulated signal reduces a PAPR of the transmitted signal.

In some aspects, the UE (and/or the network node) may select one or more subcarriers for transmitting one or more PRTs and one or more subcarriers for transmitting a data modulated signal. For example, the UE may interleave a set of PRTs (C[1]-C[N-1], as shown in FIG. 5B) and one or more subcarriers for transmitting a data modulated signal (X[0]-X[N-2], as shown in FIG. 5B). The data modulated signal may include a set of data bits, a set of resource elements (e.g., the one or more subcarriers), and/or a set of constellation symbols (e.g., QAM symbols), among other examples.

As shown in FIG. 5B, the UE may perform an inverse fast Fourier transform (iFFT) operation for the data modulated signal and an iFFT operation for the set of PRTs. The UE may combine an output of performing the iFFT operations (x(t) and c(t), as shown in FIG. 5B) to generate a signal associated with a lower PAPR relative to a PAPR associated with transmitting the data modulated signal without the set of PRTs.

Additionally, or alternatively, tone reservation may be applied to physical downlink control channel (PDCCH) symbols (e.g., symbols 0 and 1 in FIG. 5). In some aspects, a pilot may include or may be a reference signal. In some aspects, the network node may transmit a signal that is configured to improve a PAPR for a downlink transmission on the PDSCH by using tone reservation to forego transmission of data and/or pilots on the one or more reserved subcarriers.

While example 500 provides an example of tone reservation applied to PDSCH and/or PDCCH, in some aspects (e.g., when a UE applies tone reservation to uplink communications transmitted to a network node), tone reservation may be applied to physical uplink shared channel (PUSCH) and/or physical uplink control channel (PUCCH) symbols.

The use of tone reservation may involve significant overhead that may decrease overall throughput. For example, to enable the UE to identify which subcarriers to discard (e.g., the reserved subcarriers), the network node may indicate the frequency locations (e.g., using identifiers) of the subcarriers to the UE. These indications may consume communication, network, and power resources (e.g., bits) for the network node to transmit (e.g., in downlink control information) and for the UE to receive. Additionally, or alternatively, consumption of the network resources for the indications may decrease throughput available for data (e.g., associated with the PDSCH). In a communication where tone reservation is not used, an increase in PAPR may occur, which may degrade communications between the network node and the UE, and may negatively affect an efficiency of power amplification at the network node. Based at least in part on degradation of the communications, the UE and/or the network node may consume power, communication, network, and computing resources to detect and/or correct communication errors associated with the degradation.

As indicated above, FIGS. 5A and 5B provided as an example. Other examples may differ from what is described with respect to FIGS. 5A and 5B.

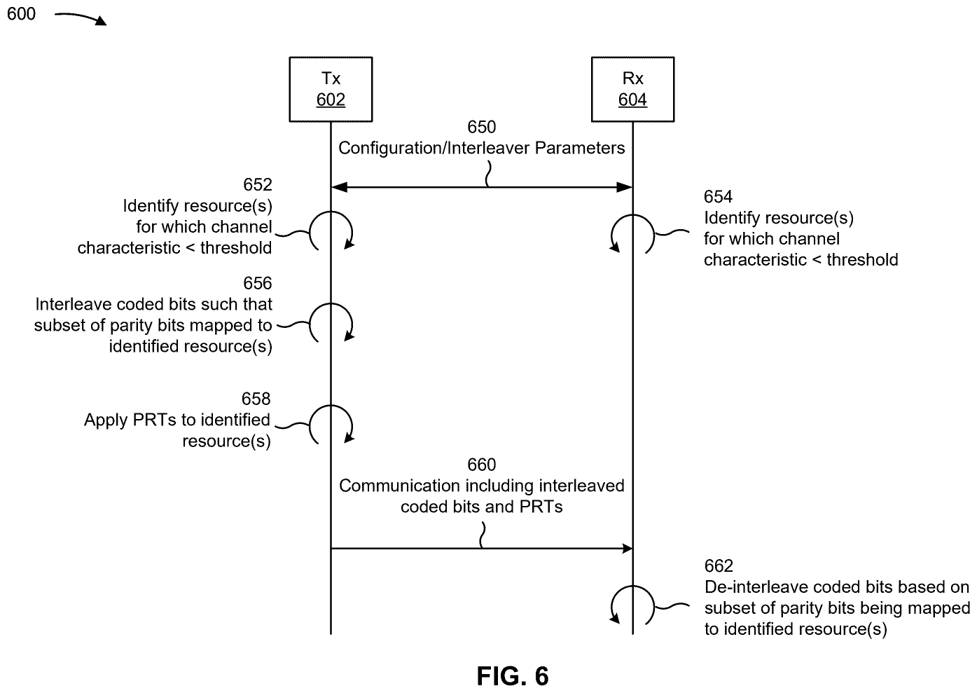

FIG. 6 is a diagram illustrating an example 600 associated with interleaver based tone reservation, in accordance with the present disclosure. As shown in FIG. 6, example 600 includes communication between a transmitter wireless communication device (Tx) 602 and a receiver wireless communication device (Rx) 604. In some aspects, the Tx 602 and the Rx 604 may be included in a wireless communication network, such as wireless communication network 100. The Tx 602 and the Rx 604 may communicate via a wireless access link, which may include an uplink and a downlink. In some aspects, the Tx 602 is a network node 110 and the Rx 604 is a UE 120. In some aspects, the Tx 602 is a UE 120 and the Rx 604 is a network node 110. In some aspects, the Tx 602 is a first UE 120 and the Rx 604 is a second UE 120.

As shown by reference number 650, the Tx 602 and the Rx 604 may transmit and/or receive configuration information and interleaver parameters. The configuration information and interleaver parameters may be received and/or transmitted in, for example, RRC signaling, DCI, or uplink control information (UCI). In some aspects, the configuration information and interleaver parameters may include information for performing interleaving and/or applying PRTs as described elsewhere herein.

As shown at reference number 652, the Tx 602 may identify one or more resources, in a plurality of resources of a communication channel, for which a channel characteristic fails to satisfy a threshold. For example, the Tx 602 may in some aspects receive a signal (e.g., a sounding reference signal (SRS)) associated with measuring the channel characteristic for each resource in the plurality of resources. The Tx 602 may then measure the channel characteristic for each resource in the plurality of resources using the signal. The Tx 602 may then identify the one or more resources by comparing a result of the measurement of the channel characteristic for each resource in the plurality of resources to the threshold. The channel characteristic may include, for example, a spectral efficiency, a capacity, a signal-to-noise ratio (SNR), or a signal-to-interference-plus-noise ratio (SINR), among other examples. Therefore, in some aspects, the threshold may be a spectral efficiency threshold, a capacity threshold, an SNR threshold, or an SINR threshold, among other examples. In some aspects, the Tx 602 may identify the one or more resources in this manner when channel reciprocity between the Tx 602 and the Rx 604 is assumed.

In some aspects, the Tx 602 identifies the one or more resources at a per-RB resolution. That is, the Tx 602 may in some aspects measure the channel characteristic on a per-RB basis, and may identify one or more RBs for which the channel characteristic fails to satisfy the threshold. In some aspects, the identification at the per-RB resolution reduces signal overhead associated with indicating the one or more resources that fail to satisfy the threshold. Additionally, or alternatively, the Tx 602 may identify the one or more resources at a per-RE resolution. That is, the Tx 602 may in some aspects measure the channel characteristic on a per-RE basis, and may identify one or more REs for which the channel characteristic fails to satisfy the threshold. In some aspects, the identification at the per-RE resolution improves granularity of channel aware interleaving, thereby further improving communication reliability.

In some aspects, the threshold is pre-configured on the Tx 602. That is, the threshold may in some aspects be pre-defined on the Tx 602 (e.g., during initial configuration of the Tx 602). Additionally, or alternatively, the Tx 602 may receive an indication of the threshold. The indication of the threshold may be received in, for example, RRC signaling, DCI, or UCI (e.g., RRC signaling, DCI, or UCI carrying the configuration information and interleaver parameters described above with respect to reference number 650).

In some aspects, the Tx 602 may transmit a communication that includes information that identifies the one or more resources for which the channel characteristic fails to satisfy the threshold. For example, the Tx 602 may transmit, to the Rx 604, a communication including information that identifies the one or more resources as identified by the Tx 602. Such a technique may be used when, for example, channel reciprocity between the Tx 602 and the Rx 604 is not assumed and the Tx 602 is configured to identify the one or more resources (e.g., rather than the Rx 604). In some aspects, the Tx 602 may transmit such a communication in, for example, RRC signaling, DCI, or UCI.

Alternatively, the Tx 602 may in some aspects identify the one or more resources for which the channel characteristic fails to satisfy the threshold based at least in part on a communication that indicates the one or more resources. For example, the Tx 602 may receive (e.g., from the Rx 604) a communication that includes information that identifies the one or more resources of the communication channel for which the channel characteristic fails to satisfy the threshold, and the Tx 602 may identify the one or more resources accordingly. Such a technique may be used when, for example, channel reciprocity between the Tx 602 and the Rx 604 is not assumed and the Rx 604 is configured to identify the one or more resources (e.g., rather than the Tx 602). In some aspects, the Tx 602 may receive the communication according to a periodicity associated with updating the information that identifies the one or more resources for which the channel characteristic fails to satisfy the threshold. That is, the Tx 602 may receive (e.g., from the Rx 604) communications identifying the one or more resources on a periodic basis such that the one or more resources can be updated (e.g., as channel conditions change). In some aspects, the Tx 602 may receive the communication in, for example, RRC signaling, DCI, or UCI (e.g., RRC signaling, DCI, or UCI carrying the configuration information and interleaver parameters described above with respect to reference number 650).

As shown at reference number 654, the Rx 604 may identify one or more resources, in the plurality of resources of the communication channel, for which the channel characteristic fails to satisfy the threshold. In some aspects, the Rx 604 may identify the one or more resources in a manner similar to that of the Tx 602, as described above with respect to reference number 650. For example, the Rx 604 may in some aspects receive a signal (e.g., an SRS) associated with measuring the channel characteristic for each resource in the plurality of resources. The Rx 604 may then measure the channel characteristic for each resource in the plurality of resources using the signal. The Rx 604 may then identify the one or more resources by comparing a result of the measurement of the channel characteristic for each resource in the plurality of resources to the threshold. In some aspects, the Rx 604 may identify the one or more resources in this manner when channel reciprocity between the Tx 602 and the Rx 604 is assumed. In some aspects, the Rx 604 identifies the one or more resources at a per-RB resolution. Additionally, or alternatively, the Rx 604 may identify the one or more resources at a per-RE resolution.

In some aspects, the threshold is pre-configured on the Rx 604. That is, the threshold may in some aspects be pre-defined on the Rx 604 (e.g., during initial configuration of the Rx 604). Additionally, or alternatively, the Rx 604 may receive an indication of the threshold. The indication of the threshold may be received in, for example, RRC signaling, DCI, or UCI (e.g., RRC signaling, DCI, or UCI carrying the configuration information and interleaver parameters described above with respect to reference number 650).

In some aspects, the Rx 604 may transmit a communication that includes information that identifies the one or more resources for which the channel characteristic fails to satisfy the threshold. For example, the Rx 604 may transmit, to the Tx 602, a communication including information that identifies the one or more resources as identified by the Rx 604. Such a technique may be used when, for example, channel reciprocity between the Tx 602 and the Rx 604 is not assumed and the Rx 604 is configured to identify the one or more resources (e.g., rather than the Tx 602). In some aspects, the Rx 604 may transmit such a communication in, for example, RRC signaling, DCI, or UCI (e.g., RRC signaling, DCI, or UCI carrying the configuration information and interleaver parameters described above with respect to reference number 650).

Alternatively, the Rx 604 may in some aspects identify the one or more resources for which the channel characteristic fails to satisfy the threshold based at least in part on a communication that indicates the one or more resources. For example, the Rx 604 may receive (e.g., from the Tx 602) a communication that includes information that identifies the one or more resources of the communication channel for which the channel characteristic fails to satisfy the threshold, and the Rx 604 may identify the one or more resources accordingly. Such a technique may be used when, for example, channel reciprocity between the Tx 602 and the Rx 604 is not assumed and the Tx 602 is configured to identify the one or more resources (e.g., rather than the Rx 604). In some aspects, the Rx 604 may receive the communication according to a periodicity associated with updating the information that identifies the one or more resources for which the channel characteristic fails to satisfy the threshold. That is, the Rx 604 may receive (e.g., from the Tx 602) communications identifying the one or more resources on a periodic basis such that the one or more resources can be updated (e.g., as channel conditions change). In some aspects, the Rx 604 may receive the communication in, for example, RRC signaling, DCI, or UCI (e.g., RRC signaling, DCI, or UCI carrying the configuration information and interleaver parameters described above with respect to reference number 650).

As shown at reference number 656, the Tx 602 may interleave a plurality of coded bits to form a plurality of interleaved coded bits. Here, the plurality of coded bits includes a set of systematic bits and a set of parity bits. In some aspects, the plurality of coded bits includes a group of bits to which a linear code, such as an LDPC code or a convolutional cod, has been applied.

In some aspects, the Tx 602 interleaves the plurality of coded bits such that a first subset of parity bits from the set of parity bits is mapped to the one or more resources for which the channel characteristic fails to satisfy the threshold. That is, when performing interleaving of the plurality of coded bits, the Tx 602 maps some parity bits to the one or more lower capacity (i.e., less reliable) resources. In some aspects, a mapping algorithm used by the Tx 602 to interleave the plurality of coded bits can be based at least in part on positions (e.g., relative positions in the frequency domain) of the one or more resources for which the channel characteristic fails to satisfy the threshold. That is, a mapping algorithm used by the Tx 602 can be configured with a rule that causes a subset of parity bits is mapped to the one or more resources of which the channel characteristic fails to satisfy the threshold. In some aspects, the mapping algorithm given the positions of the one or more lower capacity resources is identifiable by both the Tx 602 and the Rx 604 (e.g., such that the Rx 604 can use the same mapping algorithm used by the Tx 602 when the Rx 604 de-interleaves the plurality of interleaved coded bits, as described below). Here, by mapping the first subset of parity bits to the one or more lower capacity resources, the Tx 602 may reduce or minimize a quantity of systematic bits that are mapped to the one or more lower capacity resources. As a result, an impact of the relatively lower reliability of the one or more resources on reception of a communication including the plurality interleaved coded bits is reduced or minimized (e.g., as compared to an impact when conventional interleaving is used).

In some aspects, the Tx 602 interleaves the plurality of coded bits such that the set of systematic bits and a second subset of parity bits from the set of parity bits are mapped to one or more resources, in the plurality of resources of the communication channel, for which the channel characteristic satisfies the threshold. That is, when performing interleaving of the plurality of coded bits, the Tx 602 maps systematic bits and remaining parity bits (e.g., parity bits that are not mapped to the lower capacity resources) to one or more resources for which the channel characteristic satisfies the threshold.

In some aspects, the Tx 602 may transmit information that enables the Tx 602 and the Rx 604 to ensure that the Tx 602 and the Rx 604 identify the same set of resources as resources for which the channel characteristic fails to satisfy the threshold. For example, the Tx 602 may identify the one or more resources based on measuring the channel characteristic for each resource, as described above. The Tx 602 may then generate a Tx bit string that indicates whether each resource in the plurality of resources satisfies the threshold. As a particular example, the Tx 602 may generate a Tx binary word (e.g., a sequence of ones and zeroes), where each value in the Tx binary word corresponds to a different resource in the plurality of resources and indicates whether the Tx 602 has determined that the channel characteristic fails to satisfy the threshold for that resource. As an example, a value of 1 (one) associated with a particular resource may indicate that a channel characteristic for that resource satisfies the threshold, while a value of 0 (zero) associated with a particular resource may indicate that a channel characteristic for that resource fails to satisfy the threshold. The Rx 604 may determine an initial Rx bit string in a similar manner (e.g., the Tx 602 and the Rx 604 may determine respective binary words separately). Here, the Tx 602 may code the Tx bit string to obtain a set of CRC bits or parity bits (CRC/parity bits) that correspond to the coding of the Tx bit string. The Tx 602 may then transmit, and the Rx 604 may receive, a communication including the set of CRC/parity bits. Notably, the Tx 602 does not transmit the Tx bit string in this example. In some aspects, the Tx 602 may transmit, and the Rx 604 may receive, the set of CRC/parity bits in, for example, RRC signaling, DCI, or UCI. The Rx 604 may then correct the initial Rx bit string using the set of CRC/parity bits to obtain a final Rx bit string (e.g., a bit string that matches the Tx bit string). In this way, identification of the same set of resources by the Tx 602 and the Rx 604 may be ensured with minimal overhead (e.g., since only the CRC/parity bits need to be transmitted). In some aspects, bit strings may be generated by the Tx 602 and the Rx 604 at an RB-resolution to further reduce overhead (e.g., as compared to an RE-resolution).

As shown at reference number 658, the Tx 602 may apply PRTs to the identified resources. In some aspects, the Tx 602 may utilize a tone reservation technique to reduce PAPR by applying PRTs to one or more resources allocated for the transmission of the interleaved coded bits.

For example, the Tx 602 and/or the Rx 604 may select one or more tone reservation resources from the set of resources allocated to the Tx 602. The one or more tone reservation resources may be utilized to transmit one or more PRTs (e.g., instead of data).

In some aspects, the Tx 602 may identify a group of one or more tone reservation resources corresponding to resources to which only parity bits are mapped. For example, the Tx 602 may identify a group of one or more tone reservation resources corresponding to the one or more resources for which the channel characteristic fails to satisfy the threshold.

In some aspects, the Tx 602 may determine a combination of the group of tone reservation resources that reduces a PAPR associated with the transmission of a communication of the plurality of interleaved coded bits. The Tx 602 may apply PRTs to the combination of the group of tone resources.

In some aspects, the Tx 602 may apply the PRTs based at least in part on a power constraint. In some aspects, the power constraint may indicate that a power associated with transmitting the PRTs is less than a power associated with transmitting resources carrying systematic bits.

As shown at reference number 660, the Tx 602 may transmit, and the Rx 604 may receive, a communication including the plurality of interleaved coded bits and the PRTs. In some aspects, the PRTs are overlapped with a low power relative to a power associated with transmitting the resources carrying the systematic bits. By overlapping the PRTs with a low power relative to a power at which the resources carrying the systematic bits are transmitted, the Tx 602 may transmit the PRTs without a corresponding increase in an amount of data transmitted and/or without impacting an ability of the Rx 604 to receive the communication.

In some aspects, the communication is a downlink communication (e.g., when the Tx 602 is a network node 110 and the Rx 604 is a UE 120). In some aspects, the communication is an uplink communication (e.g., when the Tx 602 is a UE 120 and the Rx 604 is a network node 110). In some aspects, the communication is a sidelink communication (e.g., when the Tx 602 is a first UE 120 and the Rx 604 is a second UE 120).

As shown at reference number 662, the Rx 604 may de-interleave the plurality of interleaved coded bits to obtain a plurality of coded bits. In some aspects, the Rx 604 de-interleaves the plurality of interleaved coded bits based on the first subset of parity bits being mapped to the one or more resources for which the channel characteristic fails to satisfy the threshold. That is, when performing de-interleaving of the plurality of interleaved coded bits, the Rx 604 stores information indicating that some parity bits are mapped to the one or more lower capacity (i.e., less reliable) resources. For example, as described above, a mapping algorithm used by the Rx 604 to de-interleave the plurality of interleaved coded bits may in some aspects be based at least in part on positions (e.g., relative positions in the frequency domain) of the one or more resources for which the channel characteristic fails to satisfy the threshold. That is, similar to the mapping algorithm configured for the Tx 602, a mapping algorithm used by the Rx 604 can be configured with the rule that causes a subset of parity bits to be mapped to the one or more resources of which the channel characteristic fails to satisfy the threshold. In some aspects, as noted above, the mapping algorithm given the positions of the one or more lower capacity resources is identifiable by both the Tx 602 and the Rx 604. For example, at reference number 654, the Rx 604 should identify the same one or more lower capacity resources as identified by the Tx 602 at reference 652. Therefore, if the Tx 602 and the Rx 604 are configured with a rule that causes a subset of parity bits to be mapped to the one or more resources of which the channel characteristic fails to satisfy the threshold, then the same mapping algorithm (given the position of the one or more resources as determined by the Rx 604 and the Tx 602) should be used by the both the Tx 602 and the Rx 604. In this way, the same mapping algorithm can be determined and applied by both the Tx 602 and the Rx 604.

In some aspects, the Rx 604 de-interleaves the plurality of interleaved coded bits based on the set of systematic bits and the second subset of parity bits being mapped to one or more resources for which the channel characteristic satisfies the threshold. That is, when performing de-interleaving of the plurality of interleaved coded bits, the Rx 604 stores information indicating that systematic bits and remaining parity bits (e.g., parity bits that are not mapped to the lower capacity resources) are mapped to one or more resources for which the channel characteristic satisfies the threshold.

As indicated above, FIG. 6 is provided as an example. Other examples may differ from what is described with respect to FIG. 6.

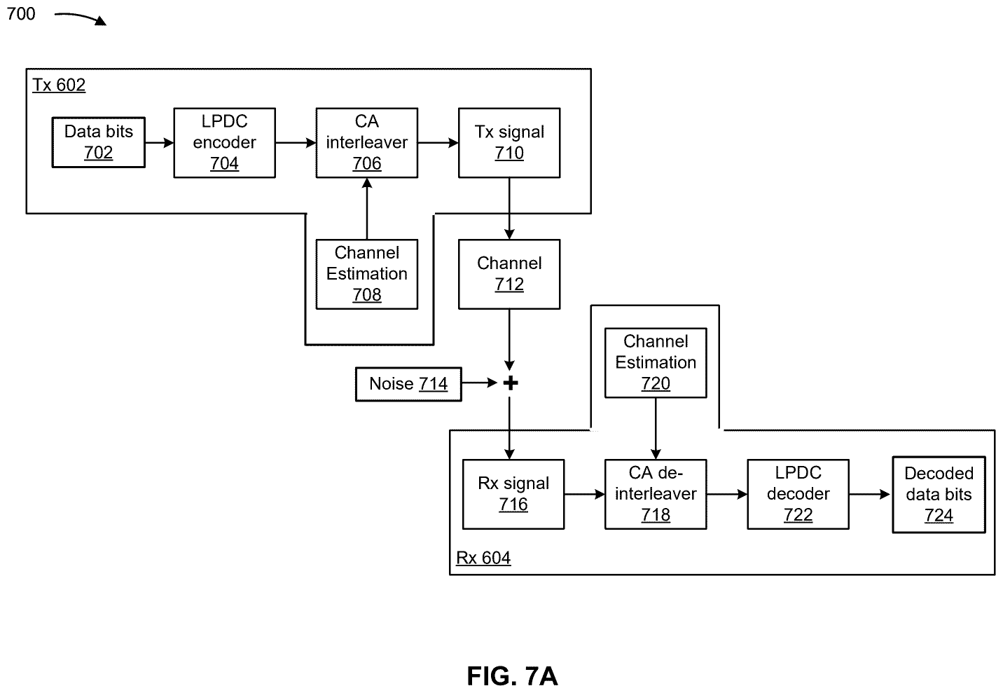

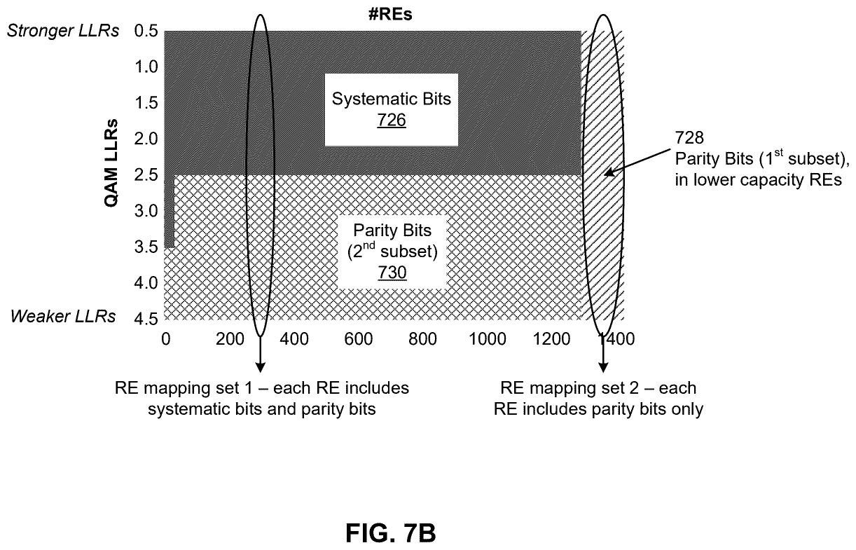

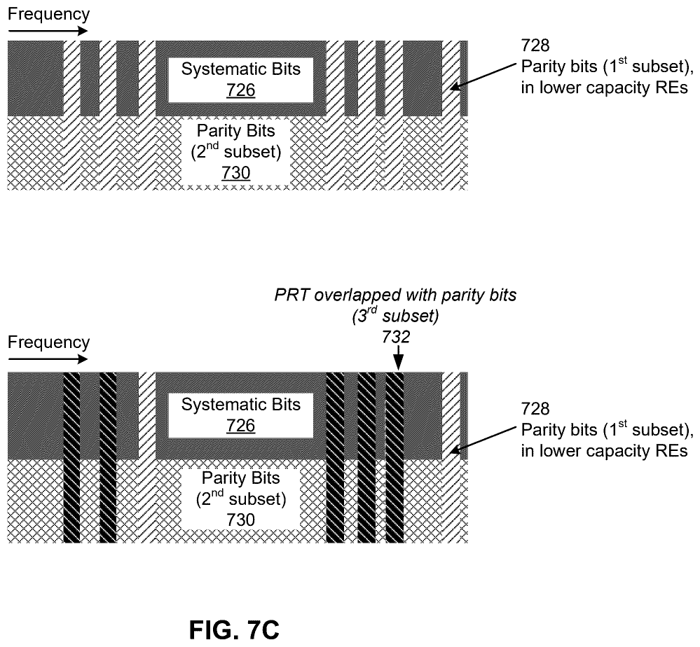

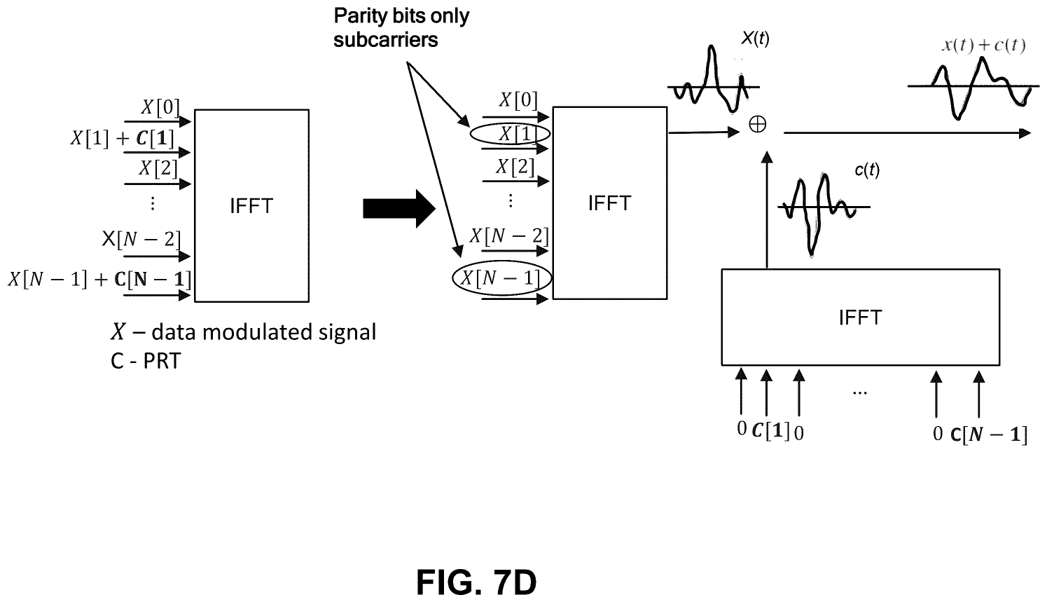

FIGS. 7A-7D are diagrams illustrating examples associated with channel aware interleaving, in accordance with the present disclosure.

FIG. 7A is a diagram illustrating an example 700 associated with transmission and reception of a communication using channel interleaving as described herein. As shown in FIG. 7A, at the Tx 602, data bits 702 are provided to an LDPC encoder 704, and an output of the LDPC encoder 704 (i.e., a plurality of coded bits) is provided to a channel aware interleaver 706. Here, the channel aware interleaver 706 receives, from a channel estimation component 708, an indication of one or more resources in the communication channel for which a channel characteristic fails to satisfy a threshold. Based on this information, the channel aware interleaver 706 maps a first subset of parity bits to LLRs corresponding to the one or more resources for which the channel characteristic fails to satisfy the threshold, as described above. In this way, the channel aware interleaver 706 takes into account conditions of the communication channel in association with interleaving the plurality of coded bits. An output of the channel aware interleaver 706 is provided for further processing and a Tx signal 710 is generated.

In some aspects, the further processing includes using a tone (e.g., a subcarrier) reservation process. Tone reservation may comprise an algorithm that identifies (e.g., reserves) data subcarriers within an allocation of resources (e.g., resources allocated for transmitting Tx signal 710) to be used for something other than transmitting data.

In some aspects, instead of identifying the data subcarriers from the entire allocation of resources, the tone reservation process may identify data subcarriers (e.g., resource elements) carrying only parity bits (e.g., the one or more resources for which the channel characteristic fails to satisfy the threshold). Additionally, or alternatively, the tone reservation process may identify data subcarriers carrying systematic bits and parity bits. Stated differently, the tone reservation process may exclude resources carrying only systematic bits.

In some aspects, a PRT may comprise a subcarrier via which an anti-peak signal is transmitted rather than data (e.g., the systematic bits and/or the parity bits). The subcarrier via which the anti-peak signal is transmitted may be orthogonal to subcarriers via which data is transmitted. The anti-peak signal may comprise a signal that, when added to the Tx signal 710, reduces the PAPR of the Tx signal 710 (e.g., due to the subcarrier being orthogonal to the subcarriers via which the system bits and the parity bits are transmitted).

In some aspects, to apply a PRT to a particular set of resources (e.g., a set of resources carrying only parity bits), the Tx 602 may not transmit the parity bits and, instead, transmit the anti-peak signal. In some aspects, the PRT may be added to the parity bits. For example, the Tx 602 may combine the anti-peak signal and the parity bits to generate a combined signal. The Tx 602 may transmit the combined signal via the particular set of resources.

In some aspects, to apply a PRT to a particular set of resources carrying only parity bits, the Tx 602 may overlap the PRT with the particular set of resources. For example, the Tx 602 may transmit the parity bits, via the particular set of resources (e.g., subcarriers), and may transmit the PRT (e.g., the anti-peak signal), via a set of resources (e.g., subcarriers) that are orthogonal to the particular set of resources. In some aspects, the PRT (e.g., the anti-peak signal) is transmitted with a low power relative to a power associated with transmitting a set of systematic bits and/or a power associated with transmitting the parity bits.

The Tx signal 710 is transmitted in a communication channel 712 (e.g., a communication channel comprising a plurality of REs). As shown, noise 714 is introduced during transmission in the communication channel 712.

An Rx 604 receives an Rx signal 716. For example, at the Rx 604, a set of antennas (e.g., antenna 234, as shown in FIG. 2) may receive the Rx signal 716 from the Tx 602 and may provide a set of received signals (e.g., R received signals) to a set of modems (e.g., modem 232, as shown in FIG. 2).

The Rx signal 716 is processed at the Rx 604. For example, the Rx signal 716 may be provided to a demodulator component (shown as DEMOD in FIG. 2) of a modem. The modem may use a demodulator component to condition (e.g., filter, amplify, downconvert, and/or digitize) the Rx signal 716 to obtain input samples. The modem may use the demodulator component to further process the input samples (e.g., for OFDM) to obtain a plurality of interleaved coded bits.

The plurality of interleaved coded bits may be provided to a channel aware de-interleaver 718. Here, the channel aware de-interleaver 718 receives, from a channel estimation component 720, an indication of the one or more resources in the communication channel for which the channel characteristic fails to satisfy the threshold. Based on this information, the channel aware de-interleaver 718 de-maps a first subset of parity bits from LLRs corresponding to the one or more resources for which the channel characteristic fails to satisfy the threshold, as described above. In this way, the channel aware de-interleaver 718 takes into account conditions of the communication channel in association with de-interleaving the plurality of interleaved coded bits. An output of the channel aware de-interleaver 718 (e.g., a plurality of de-interleaved coded bits) is provided to an LDPC decoder 722, and the LDPC decoder 722 decodes the plurality of de-interleaved coded bits to obtain a plurality of decoded data bits 724.

For example, the LDPC decoder may comprise a receive processor (e.g., receive processor 238, as shown in FIG. 2). The receive processor may process plurality of de-interleaved coded bits to obtain the plurality of decoded data bits 724. The receive processor may provide the plurality of decoded data bits 724 to a data sink (e.g., data sink 239, as shown in FIG. 2). For example, the receive processor may provide the plurality of decoded data bits 724 to a data pipeline, a data queue, and/or another type of data sink.

In some aspects, the Rx 604 performs a demodulating and/or decoding process that is based at least in part on the PRTs being applied to the one or more resources for which the channel characteristic fails to satisfy the threshold. In some aspects, because the PRTs are applied based at least in part on a power constraint, a signal corresponding to the PRTs (C[k]) may be considered as a noise term with a maximal power constraint and, therefore, can be modeled within a noise estimation on the one or more resources for which the channel characteristic fails to satisfy the threshold.

For example, the signal (C[k]) may be constructed as:

$$C [ k ] = {p}_{c} \cdot ( {c}_{1} [ k ] + j \cdot {c}_{2} [ k ] ) ,$$

where p_{c} is the amplitude of the PRT signal.

The received signal power on the resources to which the PRTs are applied may correspond to:

$${P}_{Y} = {P}_{X} + ( {P}_{C} + {σ}_{n}^{2} ) .$$

The received signal power on the resources to which PRTs are not applied may correspond to:

$${P}_{Y} = {P}_{X} + {σ}_{n}^{2} .$$

Thus, the P_{C} term can be considered within a cross-correlation matrix Rnn and a noise whitening matrix utilized in a demodulating and/or decoding process.

FIG. 7B illustrates an example of a result of interleaving as performed by the channel aware interleaver 706 that takes into account conditions of the communication channel 712. As indicated in FIG. 7B, each column of the diagram represents an RE (e.g., a subcarrier), and each row of the diagram represents an LLR of the constellation. 16 QAM is used in this example, and so there are four bits, with each row corresponding to one of the four bits. As indicated in FIG. 7B, the interleaving performed by the channel aware interleaver 706 results in a mapping of a first subset of parity bits 728 to one or more resources for which the channel characteristic fails to satisfy the threshold (e.g., lower capacity REs), while the set of systematic bits 726 and a second subset of the parity bits 730 are mapped to resources for which the channel characteristic satisfies the threshold.

FIG. 7C illustrates an example of an impact of lower capacity resources on a transmission that uses channel aware interleaving as described herein. As indicated in the upper diagram of FIG. 7C (and as described above), the channel aware interleaver 706 maps the first subset of parity bits 728 to the one or more resources for which the channel characteristic fails to satisfy the threshold, and maps the systematic bits 726 and a second subset of parity bits 730 to one or more resources for which the channel characteristic satisfies the threshold.

In some aspects, the lower capacity resources may cause transmission of bits in these resources to be unreliable due to lack of sufficient energy that causes the bits to be nulled (e.g., such that the bits are not successfully received at the receiver wireless communication device). In the case of channel aware interleaving, the nulled bits may largely include parity bits (e.g., parity bits 728 from the first subset of parity bits) rather than systematic bits 726, which increases a likelihood that coded bits received at the Rx 604 are successfully decoded (e.g., as compared to using conventional interleaving). Here, the loss of the parity bits is less impactful because the parity bits are used for error correction of the systematic bits (rather than carrying actual data).

As indicated in the lower diagram of FIG. 7C, PRTs may be applied to one or more sets of resources that include only parity bits. For example, as shown in the lower diagram of FIG. 7C, a PRT may be overlapped with a set of resources used to transmit only parity bits (e.g., parity bits 732 from a third subset of parity bits). In some aspects, the PRTs may be applied to the one or more sets of resources in a manner similar to that described above with respect to FIG. 7A.

In some aspects, as shown if FIG. 7D, the UE may perform an iFFT operation for the Tx signal 710 (X[0]-X[N-2], as shown in FIG. 7D) and an iFFT operation for the PRTs (C[1]-C[N-1], as shown in FIG. 7D). The UE may combine an output of performing the iFFT operations (x(t) and c(t), as shown in FIG. 7D) to generate a signal associated with a lower PAPR relative to a PAPR associated with transmitting the Tx signal 710 without the PRTs.

By overlapping the PRTs with resources carrying only parity bits, a PAPR (e.g., a PAPR associated with Tx signal 710) may be reduced without a decrease in throughput. Further, any loss of the parity bits that may result from overlapping the PRTs (and/or from using the lower capacity resources) is less impactful because, as stated above, the parity bits are used for error correction of the systematic bits (rather than carrying actual data).

As indicated above, FIGS. 7A-7D are provided as examples. Other examples may differ from what is described with respect to FIGS. 7A-7D.

FIG. 8 is a diagram illustrating an example process 800 performed, for example, at a wireless communication device or an apparatus of a wireless communication device, in accordance with the present disclosure. Example process 800 is an example where the apparatus or the wireless communication device (e.g., Tx 602) performs operations associated with interleaver based tone reservation.

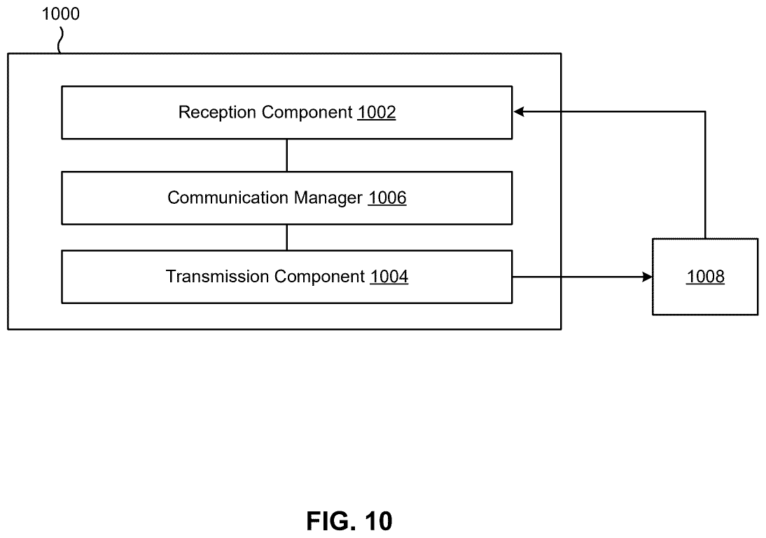

As shown in FIG. 8, in some aspects, process 800 may include interleaving a plurality of coded bits to form a plurality of interleaved coded bits, the plurality of coded bits including a set of systematic bits and a set of parity bits, wherein the plurality of coded bits is interleaved such that the set of systematic bits is mapped to a first set of resources, in a plurality of resources of a communication channel, and the set of parity bits is mapped to a second set of resources, in the plurality of resources of the communication channel, and wherein PRTs are overlapped with one or more resources of the second set of resources (block 810). For example, the wireless communication device (e.g., using communication manager 1006, depicted in FIG. 10) may interleave a plurality of coded bits to form a plurality of interleaved coded bits, the plurality of coded bits including a set of systematic bits and a set of parity bits, wherein the plurality of coded bits is interleaved such that the set of systematic bits is mapped to a first set of resources, in a plurality of resources of a communication channel, and the set of parity bits is mapped to a second set of resources, in the plurality of resources of the communication channel, and wherein PRTs are overlapped with one or more resources of the second set of resources, as described above.

As further shown in FIG. 8, in some aspects, process 800 may include transmitting a communication including the plurality of interleaved coded bits and the PRTs (block 820). For example, the wireless communication device (e.g., using transmission component 1004 and/or communication manager 1006, depicted in FIG. 10) may transmit a communication including the plurality of interleaved coded bits and the PRTs, as described above.

Process 800 may include additional aspects, such as any single aspect or any combination of aspects described below and/or in connection with one or more other processes described elsewhere herein.

In a first aspect, the PRTs are overlapped with a low power relative to a power associated with transmitting the set of systematic bits.

In a second aspect, process 800 includes transmitting or receiving a set of parameters associated with interleaving the plurality of coded bits.

In a third aspect, transmitting or receiving the set of parameters associated with interleaving the plurality of coded bits comprises periodically transmitting or receiving the set of parameters associated with interleaving the plurality of coded bits comprises.

In a fourth aspect, process 800 includes transmitting an expected error vector magnitude of the parity bits, wherein the expected error vector magnitude is based on the PRTs being overlapped with the one or more resources of the second set of resources.

In a fifth aspect, process 800 includes signaling an indication of a percentage of parity bits, of the set of parity bits, affected by the PRTs being overlapped with the second set of resources.

In a sixth aspect, the communication comprises a radio resource control communication, downlink control information, or uplink control information.

In a seventh aspect, process 800 includes identifying one or more resources, in the plurality of resources of the communication channel, for which a channel characteristic fails to satisfy a threshold, wherein the one or more resources for which the channel characteristic fails to satisfy the threshold correspond to the second set of resources.

Although FIG. 8 shows example blocks of process 800, in some aspects, process 800 may include additional blocks, fewer blocks, different blocks, or differently arranged blocks than those depicted in FIG. 8. Additionally, or alternatively, two or more of the blocks of process 800 may be performed in parallel.

FIG. 9 is a diagram illustrating an example process 900 performed, for example, at a wireless communication device or an apparatus of a wireless communication device, in accordance with the present disclosure. Example process 900 is an example where the apparatus or the wireless communication device (e.g., Rx 604) performs operations associated with interleaver based tone reservation.

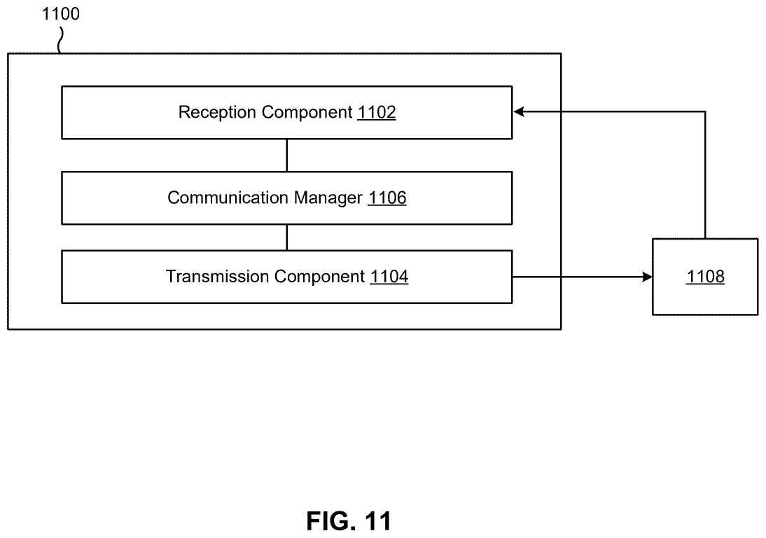

As shown in FIG. 9, in some aspects, process 900 may include receiving, via a set of subcarriers, a communication including a plurality of interleaved coded bits and PRTs, wherein the plurality of interleaved coded bits includes a set of systematic bits and a set of parity bits, wherein the plurality of interleaved coded bits is interleaved such that the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources (block 910). For example, the wireless communication device (e.g., using reception component 1102 and/or communication manager 1106, depicted in FIG. 11) may receive, via a set of subcarriers, a communication including a plurality of interleaved coded bits and PRTs, wherein the plurality of interleaved coded bits includes a set of systematic bits and a set of parity bits, wherein the plurality of interleaved coded bits is interleaved such that the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources, as described above.

As further shown in FIG. 9, in some aspects, process 900 may include decoding the communication over all subcarriers included in the set of subcarriers (block 920). For example, the wireless communication device (e.g., using communication manager 1106, depicted in FIG. 11) may decode the communication over all subcarriers included in the set of subcarriers, as described above.

Process 900 may include additional aspects, such as any single aspect or any combination of aspects described below and/or in connection with one or more other processes described elsewhere herein.

In a first aspect, the PRTs are overlapped with a low power relative to a power associated with transmitting the set of systematic bits.

In a second aspect, process 900 includes transmitting or receiving a set of parameters associated with interleaving the plurality of coded bits.

In a third aspect, transmitting or receiving the set of parameters associated with interleaving the plurality of coded bits comprises periodically transmitting or receiving the set of parameters associated with interleaving the plurality of coded bits comprises.

In a fourth aspect, process 900 includes receiving an expected error vector magnitude of the parity bits, wherein the expected error vector magnitude is based on the PRTs being overlapped with the one or more resources of the second set of resources.

In a fifth aspect, process 900 includes receiving an indication of a percentage of parity bits, of the set of parity bits, affected by the PRTs being overlapped with the second set of resources.

In a sixth aspect, the communication comprises a radio resource control communication, downlink control information, or uplink control information.

In a seventh aspect, process 900 includes identifying one or more resources, in the plurality of resources of the communication channel, for which a channel characteristic fails to satisfy a threshold, wherein the one or more resources for which the channel characteristic fails to satisfy the threshold correspond to the second set of resources.

Although FIG. 9 shows example blocks of process 900, in some aspects, process 900 may include additional blocks, fewer blocks, different blocks, or differently arranged blocks than those depicted in FIG. 9. Additionally, or alternatively, two or more of the blocks of process 900 may be performed in parallel.

FIG. 10 is a diagram of an example apparatus 1000 for wireless communication, in accordance with the present disclosure. The apparatus 1000 may be a wireless communication device (e.g., a Tx 602), or a wireless communication device may include the apparatus 1000. In some aspects, the apparatus 1000 includes a reception component 1002, a transmission component 1004, and/or a communication manager 1006, which may be in communication with one another (for example, via one or more buses and/or one or more other components). In some aspects, the communication manager 1006 is the communication manager 140 or communication manager 150 described in connection with FIG. 1. As shown, the apparatus 1000 may communicate with another apparatus 1008, such as a UE, an Rx 604, or a network node (such as a CU, a DU, an RU, or a base station), using the reception component 1002 and the transmission component 1004.

In some aspects, the apparatus 1000 may be configured to perform one or more operations described herein in connection with FIGS. 5-7B. Additionally, or alternatively, the apparatus 1000 may be configured to perform one or more processes described herein, such as process 800 of FIG. 8. In some aspects, the apparatus 1000 and/or one or more components shown in FIG. 10 may include one or more components of the wireless communication device described in connection with FIG. 2. Additionally, or alternatively, one or more components shown in FIG. 10 may be implemented within one or more components described in connection with FIG. 2. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1002 may receive communications, such as reference signals, control information, data communications, or a combination thereof, from the apparatus 1008. The reception component 1002 may provide received communications to one or more other components of the apparatus 1000. In some aspects, the reception component 1002 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 1000. In some aspects, the reception component 1002 may include one or more antennas, one or more modems, one or more demodulators, one or more MIMO detectors, one or more receive processors, one or more controllers/processors, one or more memories, or a combination thereof, of the wireless communication device described in connection with FIG. 2.

The transmission component 1004 may transmit communications, such as reference signals, control information, data communications, or a combination thereof, to the apparatus 1008. In some aspects, one or more other components of the apparatus 1000 may generate communications and may provide the generated communications to the transmission component 1004 for transmission to the apparatus 1008. In some aspects, the transmission component 1004 may perform signal processing on the generated communications (such as filtering, amplification, modulation, digital-to-analog conversion, multiplexing, interleaving, mapping, or encoding, among other examples), and may transmit the processed signals to the apparatus 1008. In some aspects, the transmission component 1004 may include one or more antennas, one or more modems, one or more modulators, one or more transmit MIMO processors, one or more transmit processors, one or more controllers/processors, one or more memories, or a combination thereof, of the wireless communication device described in connection with FIG. 2. In some aspects, the transmission component 1004 may be co-located with the reception component 1002 in one or more transceivers.

The communication manager 1006 may support operations of the reception component 1002 and/or the transmission component 1004. For example, the communication manager 1006 may receive information associated with configuring reception of communications by the reception component 1002 and/or transmission of communications by the transmission component 1004. Additionally, or alternatively, the communication manager 1006 may generate and/or provide control information to the reception component 1002 and/or the transmission component 1004 to control reception and/or transmission of communications.

The communication manager 1006 may interleave a plurality of coded bits to form a plurality of interleaved coded bits, the plurality of coded bits including a set of systematic bits and a set of parity bits, wherein the plurality of coded bits is interleaved such that the set of systematic bits is mapped to a first set of resources, in a plurality of resources of a communication channel, and the set of parity bits is mapped to a second set of resources, in the plurality of resources of the communication channel, and wherein PRTs are overlapped with one or more resources of the second set of resources. The transmission component 1004 may transmit a communication including the plurality of interleaved coded bits and the PRTs.

The transmission component 1004 may transmit or receive a set of parameters associated with interleaving the plurality of coded bits.

The transmission component 1004 may transmit an expected error vector magnitude of the parity bits, wherein the expected error vector magnitude is based on the PRTs being overlapped with the one or more resources of the second set of resources.

The communication manager 1006 may signal an indication of a percentage of parity bits, of the set of parity bits, affected by the PRTs being overlapped with the second set of resources.

The communication manager 1006 may identify one or more resources, in the plurality of resources of the communication channel, for which a channel characteristic fails to satisfy a threshold, wherein the one or more resources for which the channel characteristic fails to satisfy the threshold correspond to the second set of resources.

The number and arrangement of components shown in FIG. 10 are provided as an example. In practice, there may be additional components, fewer components, different components, or differently arranged components than those shown in FIG. 10. Furthermore, two or more components shown in FIG. 10 may be implemented within a single component, or a single component shown in FIG. 10 may be implemented as multiple, distributed components. Additionally, or alternatively, a set of (one or more) components shown in FIG. 10 may perform one or more functions described as being performed by another set of components shown in FIG. 10.

FIG. 11 is a diagram of an example apparatus 1100 for wireless communication, in accordance with the present disclosure. The apparatus 1100 may be a wireless communication device (e.g., Rx 604), or a wireless communication device may include the apparatus 1100. In some aspects, the apparatus 1100 includes a reception component 1102, a transmission component 1104, and/or a communication manager 1106, which may be in communication with one another (for example, via one or more buses and/or one or more other components). In some aspects, the communication manager 1106 is the communication manager 140 or communication manager 150 described in connection with FIG. 1. As shown, the apparatus 1100 may communicate with another apparatus 1108, such as a UE, a Tx 602, or a network node (such as a CU, a DU, an RU, or a base station), using the reception component 1102 and the transmission component 1104.

In some aspects, the apparatus 1100 may be configured to perform one or more operations described herein in connection with FIGS. 5-7B. Additionally, or alternatively, the apparatus 1100 may be configured to perform one or more processes described herein, such as process 900 of FIG. 9. In some aspects, the apparatus 1100 and/or one or more components shown in FIG. 11 may include one or more components of the wireless communication device described in connection with FIG. 2. Additionally, or alternatively, one or more components shown in FIG. 11 may be implemented within one or more components described in connection with FIG. 2. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1102 may receive communications, such as reference signals, control information, data communications, or a combination thereof, from the apparatus 1108. The reception component 1102 may provide received communications to one or more other components of the apparatus 1100. In some aspects, the reception component 1102 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 1100. In some aspects, the reception component 1102 may include one or more antennas, one or more modems, one or more demodulators, one or more MIMO detectors, one or more receive processors, one or more controllers/processors, one or more memories, or a combination thereof, of the wireless communication device described in connection with FIG. 2.

The transmission component 1104 may transmit communications, such as reference signals, control information, data communications, or a combination thereof, to the apparatus 1108. In some aspects, one or more other components of the apparatus 1100 may generate communications and may provide the generated communications to the transmission component 1104 for transmission to the apparatus 1108. In some aspects, the transmission component 1104 may perform signal processing on the generated communications (such as filtering, amplification, modulation, digital-to-analog conversion, multiplexing, interleaving, mapping, or encoding, among other examples), and may transmit the processed signals to the apparatus 1108. In some aspects, the transmission component 1104 may include one or more antennas, one or more modems, one or more modulators, one or more transmit MIMO processors, one or more transmit processors, one or more controllers/processors, one or more memories, or a combination thereof, of the wireless communication device described in connection with FIG. 2. In some aspects, the transmission component 1104 may be co-located with the reception component 1102 in one or more transceivers.

The communication manager 1106 may support operations of the reception component 1102 and/or the transmission component 1104. For example, the communication manager 1106 may receive information associated with configuring reception of communications by the reception component 1102 and/or transmission of communications by the transmission component 1104. Additionally, or alternatively, the communication manager 1106 may generate and/or provide control information to the reception component 1102 and/or the transmission component 1104 to control reception and/or transmission of communications.

The reception component 1102 may receive, via a set of subcarriers, a communication including a plurality of interleaved coded bits and PRTs, wherein the plurality of interleaved coded bits includes a set of systematic bits and a set of parity bits, wherein the plurality of interleaved coded bits is interleaved such that the set of systematic bits is mapped to a first set of resources, in a plurality of resources of a communication channel, and the set of parity bits is mapped to a second set of resources, in the plurality of resources of the communication channel, and wherein the PRTs are overlapped with one or more resources of the second set of resources. The communication manager 1106 may decode the communication over all subcarriers included in the set of subcarriers.

The transmission component 1104 may transmit or receive a set of parameters associated with interleaving the plurality of coded bits.

The reception component 1102 may receive an expected error vector magnitude of the parity bits, wherein the expected error vector magnitude is based on the PRTs being overlapped with the one or more resources of the second set of resources.

The reception component 1102 may receive an indication of a percentage of parity bits, of the set of parity bits, affected by the PRTs being overlapped with the second set of resources.

The communication manager 1106 may identify one or more resources, in the plurality of resources of the communication channel, for which a channel characteristic fails to satisfy a threshold, wherein the one or more resources for which the channel characteristic fails to satisfy the threshold correspond to the second set of resources.

The number and arrangement of components shown in FIG. 11 are provided as an example. In practice, there may be additional components, fewer components, different components, or differently arranged components than those shown in FIG. 11. Furthermore, two or more components shown in FIG. 11 may be implemented within a single component, or a single component shown in FIG. 11 may be implemented as multiple, distributed components. Additionally, or alternatively, a set of (one or more) components shown in FIG. 11 may perform one or more functions described as being performed by another set of components shown in FIG. 11.

The following provides an overview of some Aspects of the present disclosure:

Aspect 1: A method of wireless communication performed by a wireless communication device, comprising interleaving a plurality of coded bits to form a plurality of interleaved coded bits, the plurality of coded bits including a set of systematic bits and a set of parity bits, the plurality of coded bits are interleaved such that the set of systematic bits is mapped to a first set of resources, in a plurality of resources of a communication channel, and the set of parity bits is mapped to a second set of resources, in the plurality of resources of the communication channel, and peak reduction tones are overlapped with one or more resources of the second set of resources; and transmitting a communication including the plurality of interleaved coded bits and the peak reduction tones.

Aspect 2: The method of Aspect 1, wherein the peak reduction tones are overlapped with a low power relative to a power associated with transmitting the set of systematic bits.

Aspect 3: The method of any of Aspects 1-2, further comprising transmitting or receiving a set of parameters associated with interleaving the plurality of coded bits.

Aspect 4: The method of Aspect 3, wherein transmitting or receiving the set of parameters associated with interleaving the plurality of coded bits comprises periodically transmitting or receiving the set of parameters associated with interleaving the plurality of coded bits comprises.

Aspect 5: The method of any of Aspects 1-4, further comprising transmitting an expected error vector magnitude of the parity bits, the expected error vector magnitude being based at least in part on the peak reduction tones being overlapped with the one or more resources of the second set of resources.

Aspect 6: The method of Aspect 5, further comprising signaling an indication of a percentage of parity bits, of the set of parity bits, affected by the peak reduction tones being overlapped with the second set of resources.

Aspect 7: The method of any of Aspects 1-6, wherein the communication comprises a radio resource control communication, downlink control information, or uplink control information.

Aspect 8: The method of any of Aspects 1-7, further comprising identifying one or more resources, in the plurality of resources of the communication channel, for which a channel characteristic fails to satisfy a threshold, the one or more resources for which the channel characteristic fails to satisfy the threshold corresponding to the second set of resources.

Aspect 9: A method of wireless communication performed by a wireless communication device, comprising receiving, via a set of subcarriers, a communication including a plurality of interleaved coded bits and peak reduction tones, the plurality of interleaved coded bits including a set of systematic bits and a set of parity bits, the plurality of interleaved coded bits being interleaved such that the set of systematic bits is mapped to a first set of resources, in a plurality of resources of a communication channel, and the set of parity bits is mapped to a second set of resources, in the plurality of resources of the communication channel, and the peak reduction tones are overlapped with one or more resources of the second set of resources; and decoding the communication over all subcarriers included in the set of subcarriers.

Aspect 10: The method of Aspect 9, wherein the peak reduction tones are overlapped with a low power relative to a power associated with transmitting the set of systematic bits.

Aspect 11: The method of any of Aspects 9-10, further comprising transmitting or receiving a set of parameters associated with interleaving the plurality of coded bits.

Aspect 12: The method of Aspect 11, wherein transmitting or receiving the set of parameters associated with interleaving the plurality of coded bits comprises periodically transmitting or receiving the set of parameters associated with interleaving the plurality of coded bits comprises.

Aspect 13: The method of any of Aspects 9-12, further comprising receiving an expected error vector magnitude of the parity bits, the expected error vector magnitude being based at least in part on the peak reduction tones being overlapped with the one or more resources of the second set of resources.

Aspect 14: The method of Aspect 13, further comprising receiving an indication of a percentage of parity bits, of the set of parity bits, affected by the peak reduction tones being overlapped with the second set of resources.

Aspect 15: The method of any of Aspects 9-14, wherein the communication comprises a radio resource control communication, downlink control information, or uplink control information.

Aspect 16: The method of any of Aspects 9-15, further comprising identifying one or more resources, in the plurality of resources of the communication channel, for which a channel characteristic fails to satisfy a threshold, the one or more resources for which the channel characteristic fails to satisfy the threshold corresponding to the second set of resources.

Aspect 17: An apparatus for wireless communication at a device, the apparatus comprising one or more processors; one or more memories coupled with the one or more processors; and instructions stored in the one or more memories and executable by the one or more processors to cause the apparatus to perform the method of one or more of Aspects 1-16.

Aspect 18: An apparatus for wireless communication at a device, the apparatus comprising one or more memories and one or more processors coupled to the one or more memories, the one or more processors configured to cause the device to perform the method of one or more of Aspects 1-16.

Aspect 19: An apparatus for wireless communication, the apparatus comprising at least one means for performing the method of one or more of Aspects 1-16.

Aspect 20: A non-transitory computer-readable medium storing code for wireless communication, the code comprising instructions executable by one or more processors to perform the method of one or more of Aspects 1-16.

Aspect 21: A non-transitory computer-readable medium storing a set of instructions for wireless communication, the set of instructions comprising one or more instructions that, when executed by one or more processors of a device, cause the device to perform the method of one or more of Aspects 1-16.

Aspect 22: A device for wireless communication, the device comprising a processing system that includes one or more processors and one or more memories coupled with the one or more processors, the processing system configured to cause the device to perform the method of one or more of Aspects 1-16.

Aspect 23: An apparatus for wireless communication at a device, the apparatus comprising one or more memories and one or more processors coupled to the one or more memories, the one or more processors individually or collectively configured to cause the device to perform the method of one or more of Aspects 1-16.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware or a combination of hardware and at least one of software or firmware. “Software” shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise. As used herein, a “processor” is implemented in hardware or a combination of hardware and software. It will be apparent that systems or methods described herein may be implemented in different forms of hardware or a combination of hardware and software. The actual specialized control hardware or software code used to implement these systems or methods is not limiting of the aspects. Thus, the operation and behavior of the systems or methods are described herein without reference to specific software code, because those skilled in the art will understand that software and hardware can be designed to implement the systems or methods based, at least in part, on the description herein. A component being configured to perform a function means that the component has a capability to perform the function, and does not require the function to be actually performed by the component, unless noted otherwise.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (for example, a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” and similar terms are intended to be open-ended terms that do not limit an element that they modify (for example, an element “having” A may also have B). Further, the phrase “based on” is intended to mean “based on or otherwise in association with” unless explicitly stated otherwise. Also, as used herein, the term “or” is intended to be inclusive when used in a series and may be used interchangeably with “and/or,” unless explicitly stated otherwise (for example, if used in combination with “either” or “only one of”). It should be understood that “one or more” is equivalent to “at least one.”

Even though particular combinations of features are recited in the claims or disclosed in the specification, these combinations are not intended to limit the disclosure of various aspects. Many of these features may be combined in ways not specifically recited in the claims or disclosed in the specification. The disclosure of various aspects includes each dependent claim in combination with every other claim in the claim set.

What is claimed is:

1. A wireless communication device for wireless communication, comprising:
one or more memories; and
one or more processors, coupled to the one or more memories, configured to cause the wireless communication device to:
interleave a plurality of coded bits to form a plurality of interleaved coded bits, the plurality of coded bits including a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein peak reduction tones are overlapped with one or more resources of the second set of resources; and
transmit a communication including the plurality of interleaved coded bits and the peak reduction tones.

2. The wireless communication device of claim 1, wherein the peak reduction tones are overlapped with a low power relative to a power associated with transmitting the set of systematic bits.

3. The wireless communication device of claim 1, wherein the one or more processors are further configured to cause the wireless communication device to:
transmit or receive a set of parameters associated with interleaving the plurality of coded bits.

4. The wireless communication device of claim 3, wherein the one or more processors, to cause the wireless communication device to transmit or receive the set of parameters associated with interleaving the plurality of coded bits, are configured to cause the wireless communication device to:
periodically transmit or receive the set of parameters associated with interleaving the plurality of coded bits comprises.

5. The wireless communication device of claim 1, wherein the one or more processors are further configured to cause the wireless communication device to: transmit an expected error vector magnitude of the parity bits, wherein the expected error vector magnitude is based on the peak reduction tones being overlapped with the one or more resources of the second set of resources.

6. The wireless communication device of claim 5, wherein the one or more processors are further configured to cause the wireless communication device to:
signal an indication of a percentage of parity bits, of the set of parity bits, associated with the peak reduction tones being overlapped with the second set of resources.

7. The wireless communication device of claim 1, wherein the communication comprises a radio resource control communication, downlink control information, or uplink control information.

8. The wireless communication device of claim 1, wherein the one or more processors are further configured to cause the wireless communication device to:
identify one or more resources, in the plurality of resources of the communication channel, for which a channel characteristic fails to satisfy a threshold, wherein the one or more resources for which the channel characteristic fails to satisfy the threshold correspond to the second set of resources.

9. A wireless communication device for wireless communication, comprising:
one or more memories; and
one or more processors, coupled to the one or more memories, configured to cause the wireless communication device to:
receive, via a set of subcarriers, a communication including a plurality of interleaved coded bits and peak reduction tones, wherein the plurality of interleaved coded bits includes a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein the peak reduction tones are overlapped with one or more resources of the second set of resources; and
decode the communication over all subcarriers included in the set of subcarriers.

10. The wireless communication device of claim 9, wherein the peak reduction tones are overlapped with a low power relative to a power associated with transmitting the set of systematic bits.

11. The wireless communication device of claim 9, wherein the one or more processors are further configured to cause the wireless communication device to:
transmit or receive a set of parameters associated with interleaving a plurality of coded bits.

12. The wireless communication device of claim 11, wherein the one or more processors, to cause the wireless communication device to transmit or receive the set of parameters associated with interleaving the plurality of coded bits, are configured to cause the wireless communication device to:
periodically transmit or receive the set of parameters associated with interleaving the plurality of coded bits comprises.

13. The wireless communication device of claim 9, wherein the one or more processors are further configured to cause the wireless communication device to:
receive an expected error vector magnitude of the parity bits, wherein the expected error vector magnitude is based on the peak reduction tones being overlapped with the one or more resources of the second set of resources.

14. The wireless communication device of claim 13, wherein the one or more processors are further configured to cause the wireless communication device to:
receive an indication of a percentage of parity bits, of the set of parity bits, affected by the peak reduction tones being overlapped with the second set of resources.

15. The wireless communication device of claim 9, wherein the communication comprises a radio resource control communication, downlink control information, or uplink control information.

16. The wireless communication device of claim 9, wherein the one or more processors are further configured to cause the wireless communication device to:
identify one or more resources, in the plurality of resources of the communication channel, for which a channel characteristic fails to satisfy a threshold, wherein the one or more resources for which the channel characteristic fails to satisfy the threshold correspond to the second set of resources.

17. A method of wireless communication performed by a wireless communication device, comprising:
interleaving a plurality of coded bits to form a plurality of interleaved coded bits, the plurality of coded bits including a set of systematic bits and a set of parity bits, wherein the set of systematic bits is mapped to a first set of resources, in a plurality of resources of a communication channel, and the set of parity bits is mapped to a second set of resources, in the plurality of resources of the communication channel, and wherein peak reduction tones are overlapped with one or more resources of the second set of resources; and
transmitting a communication including the plurality of interleaved coded bits and the peak reduction tones.

18. The method of claim 17, wherein the peak reduction tones are overlapped with a low power relative to a power associated with transmitting the set of systematic bits.

19. The method of claim 17, further comprising:
transmitting an expected error vector magnitude of the parity bits, wherein the expected error vector magnitude is based on the peak reduction tones being overlapped with the one or more resources of the second set of resources.

20. The method of claim 19, further comprising:
signaling an indication of a percentage of parity bits, of the set of parity bits, affected by the peak reduction tones being overlapped with the second set of resources.
